(19) United States
(12) Patent Application Publication
(10) Pub. No.: US 2026/0068393 A1
(43) Pub. Date: Mar. 5, 2026

(54) DISPLAY APPARATUS

(71) Applicant: LG Display Co., Ltd., Seoul (KR)

(72) Inventors: Seongsoo CHO, Paju-si (KR); WooSung KIM, Paju-si (KR); Hyunseok NA, Paju-si (KR); SangHak SHIN, Paju-si (KR)

(73) Assignee: LG Display Co., Ltd., Seoul (KR)

(21) Appl. No.: 19/277,875

(22) Filed: Jul. 23, 2025

(30) Foreign Application Priority Data
Sep. 2, 2024 (KR) 10-2024-0118536

(51) Int. Cl. H10H 29/80; H01L 25/16; H10H 29/34; H10H 29/37; H10H 29/49; H10H 29/855

(52) U.S. Cl. CPC H10H 29/8323; H10H 29/345; H10H 29/37; H10H 29/49; H10H 29/8325; H10H 29/8552

(57) ABSTRACT

A display device is provided with, a substrate, a display area and a non-display area, a pixel driving circuit in the display area on the substrate, an insulating layer on the pixel driving circuit, a bank disposed in a plurality of sub-pixels including a first sub-pixel and a second sub-pixel on the insulating layer, a first electrode disposed on the bank and including a central area, an edge area, and a reflection area between the central area and the edge area, and a light emitting device electrically connected to the first electrode on the first electrode and overlapping the bank. A width of a reflection area of the first electrode in the first sub-pixel is different from a width of a reflection area of the first electrode in the second sub-pixel.

### CROSS-REFERENCE TO RELATED APPLICATIONS

This application claims the benefit of and priority to Korean Patent Application No. 10-2024-0118536 filed on Sep. 2, 2024, the entire contents of which are incorporated herein by reference for all purposes.

### BACKGROUND

### 1. Technical Field

The present disclosure relates to a display device.

### 2. Description of Related Art

The display device is applied to various electronic devices such as TVs, mobile phones, laptops, and tablets.

The display devices include an organic light emitting display (OLED) that emit light by themselves and a liquid crystal display (LCD) that require a separate light source.

Recently, a display device including a light emitting diode (LED) has attracted attention as a next-generation display device. The light emitting diode is made of an inorganic material, not an organic material. Accordingly, compared to the liquid crystal display or the organic light emitting display device, the display device including the light emitting diode has a faster lighting speed, excellent luminous efficiency, and displays an image having high luminance.

In the case of a display device including a light emitting device, a process of transferring a plurality of light emitting devices on a substrate is required. However, during the transfer process, an error may occur in which the light emitting device cannot be transferred to a correct position due to various reasons.

The description of related art should not be considered prior art merely because it is mentioned in or associated with this section. The description of related art includes information that describes one or more aspects of the subject technology, and the description in this section does not limit the scope of the invention.

### SUMMARY

The present disclosure has been made in view of the above problems and it is an aspect of the present disclosure to provide a display device that can reduce errors that can occur during a transfer process of light emitting devices.

In accordance with an aspect of the present disclosure, the above and other technical effects can be accomplished by the provision of a display device comprising a substrate, a display area and a non-display area, a pixel driving circuit in the display area on the substrate, an insulating layer on the pixel driving circuit, a bank disposed in a plurality of sub-pixels including a first sub-pixel and a second sub-pixel on the insulating layer, a first electrode disposed on the bank and including a central area, an edge area, and a reflection area between the central area and the edge area, and a light emitting device disposed on the first electrode and electrically connected to the first electrode and overlapping the bank, wherein a width of the reflection area of the first electrode in the first sub-pixel is different from a width of the reflection area of the first electrode in the second sub-pixel.

In addition, in accordance with an aspect of the present disclosure, the above and other technical effects can be accomplished by the provision of a display device comprising a display area including a first display area, a second display area, and a third display area between the first display area and the second display area, a plurality of light emitting devices disposed in a plurality of sub-pixels having a matrix structure in the display area, and a plurality of first electrodes electrically connected to the plurality of light emitting devices in the plurality of sub-pixels, each first electrode including a central area, an edge area, and a reflection area between the central area and the edge area, wherein widths of the reflection areas of the plurality of first electrodes are different from each other in the plurality of sub-pixels in the third display area.

In addition, in accordance with an aspect of the present disclosure, the above and other technical effects can be accomplished by the provision of a display device comprising a display area includes a first display area, a second display area at a right side of the first display area, a third display area between the first display area and the second display area, a fourth display area at a left side of the first display area, a fifth display area below the fourth display area; and a sixth display area between the fourth display area and the fifth display area, a plurality of light emitting devices in a plurality of sub-pixels having a matrix structure in the display area, and a plurality of first electrodes electrically connected to the plurality of light emitting devices in the plurality of sub-pixels and including a central area, an edge area, and a reflection area between the central area and the edge area, wherein a width of the reflection area of the plurality of first electrodes in the plurality of sub-pixels in the third display area gradually increases or decreases as a column of the matrix structure increases, and wherein a width of the reflection area of the plurality of first electrodes in the plurality of sub-pixels in the sixth display area gradually increases or decreases as a row of the matrix structure increases.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is an exploded perspective view of a display device according to an embodiment of the present disclosure.

FIG. 2 is a plan view of a display device according to an embodiment of the present disclosure.

FIG. 3 is an enlarged view of a display device according to an embodiment of the present disclosure.

FIG. 4 is a diagram illustrating a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIG. 10A is a plan view illustrating a transfer area of a display device according to an embodiment of the present disclosure.

FIG. 10B is a plan view illustrating a transfer area of a display device according to another embodiment of the present disclosure.

FIGS. 11A and 11B are a cross-sectional view and a plan view of a sub-pixel according to an embodiment of the present disclosure.

FIGS. 12A and 12B are a cross-sectional view and a plan view of a sub-pixel according to another embodiment of the present disclosure.

FIGS. 13A and 13B are a cross-sectional view and a plan view of a sub-pixel according to another embodiment of the present disclosure.

FIGS. 14A and 14B are a cross-sectional view and a plan view of a sub-pixel according to another embodiment of the present disclosure.

FIG. 15 illustrates a plurality of sub-pixels disposed in a X region of FIG. 10A according to an embodiment of the present disclosure, for example, in a region near a first boundary line between a first transfer region and a second transfer region.

FIG. 16 illustrates a plurality of sub-pixels disposed in a X region of FIG. 10A according to another embodiment of the present disclosure, for example, in a region near a first boundary line between a first transfer region and a second transfer region.

FIG. 17 illustrates a plurality of sub-pixels disposed in a Y region of FIG. 10A according to another embodiment of the present disclosure, for example, in a region near a second boundary line between a first transfer region and a third transfer region.

FIG. 18 illustrates a plurality of sub-pixels disposed in a Y region of FIG. 10A according to another embodiment of the present disclosure, for example, in a region near a second boundary line between a first transfer region and a third transfer region.

FIG. 19 illustrates a plurality of sub-pixels disposed in a Z region of FIG. 10A according to another embodiment of the present disclosure, for example, in a nearby region where a first boundary line between a first transfer region and a second transfer region and a second boundary line between a first transfer region and a third transfer region intersect.

FIG. 20 illustrates a plurality of sub-pixels disposed in a Z region of FIG. 10A according to another embodiment of the present disclosure, for example, in a nearby region where a first boundary line between a first transfer region and a second transfer region and a second boundary line between a first transfer region and a third transfer region intersect.

FIGS. 21 to 24 are diagrams illustrating devices to which a display device according to embodiments of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where “comprise,” “have” and “include” described in the present disclosure are used, another portion may be added unless “only˜” is used. The terms of a singular form may include plural forms unless referred to the contrary. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.” In interpreting the components, it is interpreted as including the error range even if there is no separate explicit description of the error range.

In describing a position relationship, for example, when the position relationship is described as “upon˜,” “above˜,” “below˜” and “next to˜,” one or more portions may be disposed between two other portions unless “just” or “direct” is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

A description of a time relationship may include a case in which the temporal precedence relationship is described as “after,” “following,” or “before,” etc., and is not continuous unless “right away” or “directly,” is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “connected,” or “attached” to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction,” “second direction,” “third direction,” “X-axis direction,” “Y-axis direction,” and “Z-axis direction” should not be interpreted only as a geometric relationship perpendicular to each other, but may mean that the configuration of the present disclosure has a wider direction within a range in which the configuration of the present disclosure may functionally act.

Features of each of the various embodiments of the present specification may be partially or entirely coupled or combined with each other, technically various interworking and driving are possible, and each of the embodiments may be independently implemented with respect to each other or may be implemented together in a related relationship.

Hereinafter, one embodiment of the present disclosure will be described in detail with reference to the accompanying drawings.

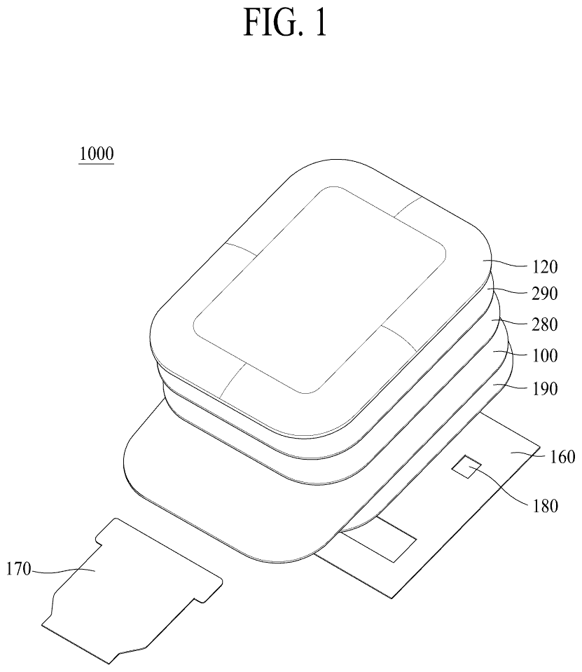

FIG. 1 is a perspective view illustrating a display device according to an embodiment of the present disclosure.

Referring to FIG. 1, a display device 1000 according to an embodiment of the present disclosure may include a display panel 100, a polarizing layer 280, an adhesive layer 290, a cover member 120, a support substrate 190, a flexible circuit board 170, and a printed circuit board 160.

The display panel 100 may implement information, a video, and/or an image provided to a user.

The polarizing layer 280 may be disposed on the display panel 100. The polarizing layer 280 may prevent or reduce light generated from an external light source from entering the display panel 100 and affecting a light emitting element or the like.

The adhesive layer 290 may attach the cover member 120 to the display panel 100. The adhesive layer 290 may be disposed between the polarizing layer 280 and the cover member 120 to attach the cover member 120 to the polarizing layer 280. The adhesive layer 290 may include an optically clear adhesive (OCA), an optically clear resin (OCR), a pressure sensitive adhesive (PSA) or the like, but embodiments of the present disclosure are not limited thereto.

The cover member 120 may be disposed on the polarizing layer 280. The cover member 120 may be disposed on the adhesive layer 290. The cover member 120 may be a member for protecting the display panel 100. The cover member 120 may be formed of a transparent material.

The support substrate 190 may be disposed between the display panel 100 and the printed circuit board 160. The support substrate 190 may reinforce rigidity of the display panel 100. The support substrate 190 may be a back plate, but embodiments of the present disclosure are not limited thereto.

The flexible circuit board 170 and the printed circuit board 160 may be disposed on a bottom of the display panel 100. The flexible circuit board 170 and the printed circuit board 160 may be disposed on at least one edge of the display panel 100, but embodiments of the present disclosure are not limited thereto. One side of the flexible circuit board 170 may be attached to the display panel 100, and the other side of the flexible circuit board 170 may be attached to the printed circuit board 160, but embodiments of the present disclosure are not limited thereto. The flexible circuit board 170 may be a flexible film, but embodiments of the present disclosure are not limited thereto.

The printed circuit board 160 may include at least one hole 180, but embodiments of the present disclosure are not limited thereto. An internal component that senses ambient light or temperature, which may be provided to a plurality of sensors, may be disposed in an area corresponding to the at least one hole 180. For example, the internal component may include an ambient light sensor (ALS) or a temperature sensor, but embodiments of the present disclosure are not limited thereto. For example, the hole 180 may be a through hole, etc., but embodiments of the present disclosure are not limited thereto.

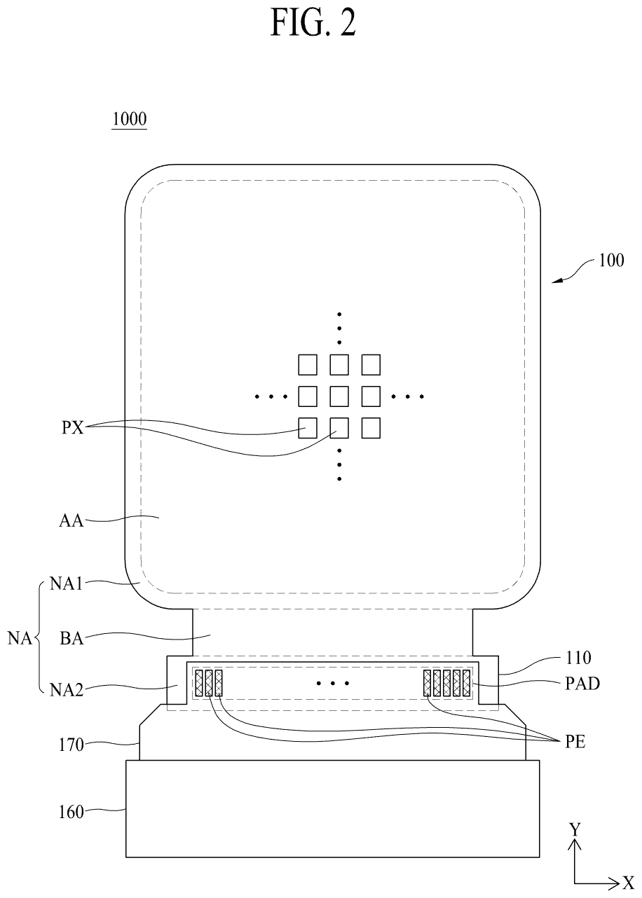

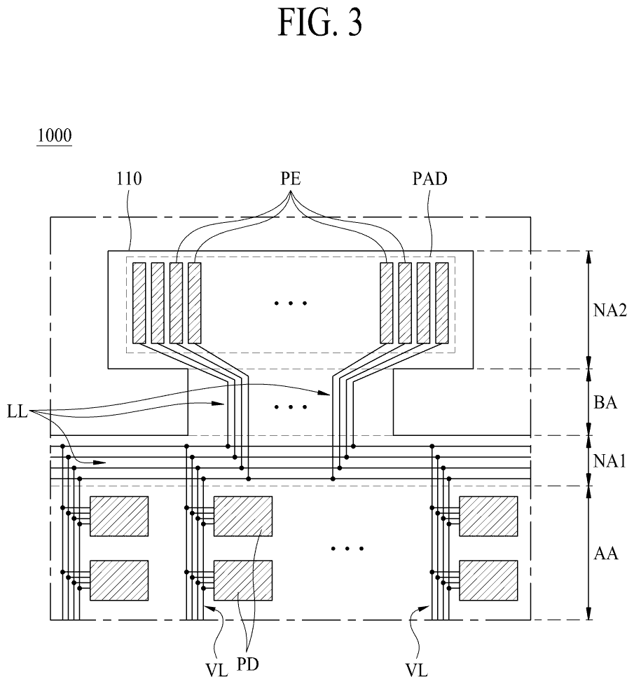

FIG. 2 is a plan view of a display device according to an embodiment of the present disclosure. And, FIG. 3 is an enlarged view of a display device according to an embodiment of the present disclosure.

Referring to FIGS. 2 and 3, the display device 1000 may include the display panel 100, the flexible circuit board 170, and the printed circuit board 160.

The display panel 100 may include a substrate 110. The substrate 110 may be a member that supports other components of the display device 1000. The substrate 110 may be made of an insulating material. For example, the substrate 110 may be made of glass or resin. Also, the substrate 110 may be made of a material having flexibility. For example, the substrate 110 may be made of a plastic material having flexibility, such as polyimide (PI). However, embodiments of the present disclosure are not limited thereto.

For example, the display panel 100 may include a display area AA and a non-display area NA. For example, the substrate 110 may include the display area AA and the non-display area NA. The display area AA and the non-display area NA are not limited to the substrate 110 but may be described throughout the display device 1000.

The display area AA may be an area in which an image is displayed. The display area AA may include a plurality of pixels PX. Each of the plurality of pixels PX may include a plurality of sub-pixels. A plurality of light emitting elements may be disposed in each of the plurality of sub-pixels. A plurality of light emitting elements may be configured to be different according to a type of the display device 1000. For example, when the display device 1000 is an inorganic light emitting display device, the light emitting element may be a light-emitting diode (LED), a micro light-emitting diode (Micro-LED), or a mini-light-emitting diode (MLED), but embodiments of the present disclosure are not limited thereto.

The display area AA may be configured in various shapes according to the design of the display device 1000. For example, the display area AA may be configured in a rectangular shape having four rounded corners, but configurations of the present disclosure are not limited thereto. For another example, the display area AA may be configured in a rectangular having four corners or circular shape, but configurations of the present disclosure are not limited thereto.

Referring to FIG. 3, a plurality of pixel driving circuits PD may be disposed in the display area AA. The plurality of pixel driving circuits PD may be circuits for driving light emitting elements of the plurality of sub-pixels. Each of the plurality of pixel driving circuits PD may include a plurality of transistors including driving transistors and storage capacitors. In addition, each of the plurality of pixel driving circuits PD may control a light emitting operation of the plurality of light emitting elements by supplying a control signal, a power source, and a driving current to the light emitting elements of the plurality of sub-pixels. For example, the pixel driving circuit PD may include a power line and a signal line for controlling light emission on/off and/or light emission time of the light emitting element. For example, the plurality of pixel driving circuits PD may be driving drivers manufactured using a metal-oxide-silicon field effect transistor (MOSFET) manufacturing process on a semiconductor substrate, but embodiments of the present disclosure are not limited thereto. The driving driver includes the plurality of pixel driving circuits PD and may drive the plurality of sub-pixels.

The non-display area NA may be an area in which no image is displayed. Various wirings, circuits, and the like for driving the plurality of pixels PX of the display area AA may be disposed in the non-display area NA. For example, various wirings and driving circuits may be mounted in the non-display area NA. Also, a pad part PAD connected to an integrated circuit, a printed circuit, and the like may be disposed in the non-display area NA, but embodiments of the present disclosure are not limited thereto.

For example, the driving circuit may be a data driving circuit and/or a gate driving circuit, but embodiments of the present disclosure are not limited thereto. Wirings to which a control signal for controlling the driving circuits is supplied may be disposed in the non-display area NA. For example, the control signal may include various timing signals including a clock signal, an input data enable signal, and synchronization signals, but embodiments of the present disclosure are not limited thereto. The control signal may be received through the pad part PAD. For example, link lines LL for transmitting a signal may be disposed in the non-display area NA. For example, a driving component such as the flexible circuit board 170 and the printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 is an area extending from the bending area BA, and the pad part PAD may be disposed. For example, the bending area BA may be bent, and a remaining area of the substrate 110 except for the bending area BA may be flat. In this case, as the bending area BA is bent, the second non-display area NA2 may be disposed on a rear surface of the display area AA. However, embodiments of the present disclosure are not limited thereto.

A plurality of link lines LL may be disposed in the non-display area NA. The plurality of link lines LL may be wirings for transmitting various signals from one or more flexible circuit boards (or flexible films) 170 and the printed circuit board 160 to the display area AA. The plurality of link lines LL may extend from a plurality of pad electrodes PE of the second non-display area NA2 toward the bending area BA and the first non-display area NA1, and may be electrically connected to a plurality of driving lines VL of the display area AA. The plurality of pixel driving circuits PD may be driven by receiving signals from one or more flexible circuit boards (or flexible films) 170 and the printed circuit board 160 through the driving line VL in the display area AA and the link line LL in the non-display area NA.

For example, the plurality of driving lines VL may be wirings for transmitting a signal output from the flexible circuit board (or flexible film) 170 and the printed circuit board 160 to the plurality of pixel driving circuits PD with the plurality of link lines LL. The plurality of driving lines VL may be disposed in the display area AA and electrically connected to each of the plurality of pixel driving circuits PD. The plurality of driving lines VL may extend from the display area AA toward the non-display area NA and may be electrically connected to the plurality of link lines LL. Accordingly, the signal output from the flexible circuit board (or flexible film) 170 and the printed circuit board 160 may be transmitted to each of the plurality of pixel driving circuits PD through the plurality of link lines LL and the plurality of driving lines VL.

As the bending area BA is bent, portions of the plurality of link lines LL may also be bent. Stress is concentrated on a portion of the bent link line LL, and thus, a crack may occur in the link line LL. Accordingly, the plurality of link lines LL may be formed of a conductive material having excellent ductility in order to reduce cracks when the bending area BA is bent. For example, the plurality of link lines LL may be formed of a conductive material having excellent ductility, such as gold (Au), silver (Ag), aluminum (Al), and the like, but embodiments of the present disclosure are not limited thereto. Also, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), an alloy of silver (Ag) and magnesium (Mg), or the like, but embodiments of the present disclosure are not limited thereto. The plurality of link lines LL may be a multilayer structure including various conductive materials. For example, the plurality of link lines LL may be a triple layer structure including titanium (Ti), aluminum (Al), and titanium (Ti), but embodiments of the present disclosure are not limited thereto.

A plurality of link lines LL may be configured in various shapes to reduce stress. At least a portion of the plurality of link lines LL disposed on the bending area BA may extend in a same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link line LL disposed on the bending area BA may extend in a direction inclined to the one direction. For another example, at least a portion of the plurality of link lines LL may include patterns of various shapes. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but embodiments of the present disclosure are not limited thereto. Therefore, in order to minimize the stress concentrated on the plurality of link lines LL and the corresponding crack, the shape of the plurality of link lines LL may be formed in various shapes including the above-described shape, but embodiments of the present disclosure are not limited thereto.

According to the present disclosure, a width of the second non-display area NA2 in which the plurality of pad electrodes PE are disposed may be wider than a width of the bending area BA in which only the plurality of link lines LL is disposed. Also, a width of the display area AA in which the plurality of sub-pixels are disposed may be wider than the width of the bending area BA in which only the plurality of link wirings LL are disposed. Although the width of the bending area BA is shown to be narrower than a width of other areas of the substrate 110, a shape of the substrate 110 including the bending area BA is exemplary, and embodiments of the present disclosure are not limited thereto.

A pad part PAD including a plurality of pad electrodes PE may be disposed in the second non-display area NA2. A driving component including one or more the flexible circuit boards (or flexible films) 170 and the printed circuit board 160 may be attached to or bonded to the pad part PAD. The plurality of pad electrodes PE of the pad part PAD are electrically connected to one or more flexible circuit boards (or flexible films) 170, and various signals (or power) received from the printed circuit board 160 and the flexible circuit board (or flexible film) 170 may be transmitted to the plurality of pixel driving circuits PD of the display area AA.

The flexible circuit board (or flexible film) 170 may be a film in which various components are disposed on a base film having flexibility. For example, a driving IC such as a gate driver IC or a data driver IC may be disposed on the flexible circuit board (or flexible film), but embodiments of the present disclosure are not limited thereto. The driving IC may be a component that processes data and a driving signal for displaying an image. The driving IC may be disposed by a method of chip on glass (COG) or chip on film (COF) or a tape carrier package (TCP) depending on a method of being mounted, but embodiments of the present disclosure are not limited thereto. The flexible circuit board (or flexible film) 170 may be attached to or bonded on the plurality of pad electrodes PE through a conductive adhesive layer, but embodiments of the present disclosure are not limited thereto.

The printed circuit board 160 may be a component electrically connected to one or more flexible circuit boards (or flexible films) 170, and supplying signals to the driving IC. The printed circuit board 160 may be disposed on one side of the flexible circuit board (or flexible film) 170, and may be electrically connected to the flexible circuit board (or flexible film). Various components for supplying various signals to the driving IC may be disposed on the printed circuit board 160. For example, various components, such as a timing controller, a power supply unit, a memory, a processor, etc., may be disposed on the printed circuit board 160. For example, the printed circuit board 160 may include a power management integrated circuit (PMIC), but embodiments of the present disclosure are not limited thereto.

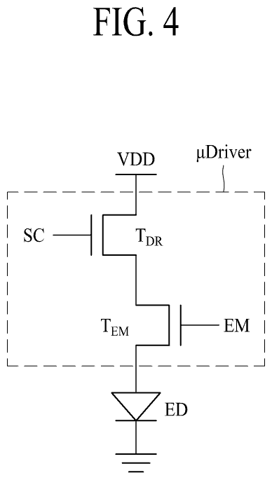

FIG. 4 is a diagram illustrating a circuit structure according to an embodiment of the present disclosure.

FIG. 4 illustrates that one light emitting device ED is connected to one micro-driver (μDriver), but is not limited thereto. For example, eight light emitting devices ED may be connected to one micro-driver (μDriver). For another example, 16 light emitting devices ED may be connected to one micro-driver (μDriver), 32 light emitting devices ED or 64 light emitting devices ED may be connected to one micro-driver (μDriver) at the same time. The light emitting device ED may be a micro light emitting device (μLED).

One micro-driver (μDriver) may include a driving transistor T_{DR} and a light emitting transistor T_{EM}, but embodiments of the present disclosure are not limited thereto.

For example, a high potential power voltage VDD may be applied to a first electrode of the driving transistor T_{DR}, a first electrode of the light emitting transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current power source, and a fixed reference voltage Vref may be applied to each frame, but embodiments of the present disclosure are not limited thereto.

The second electrode of the driving transistor T_{DR} may be connected to a first electrode of the light emitting transistor T_{EM}, the light emitting device ED may be connected to a second electrode of the light emitting transistor T_{EM}, and a light emitting signal EM may be applied to a gate electrode of the light emitting transistor T_{EM}. The light emitting signal EM applied to the gate electrode of the light emitting transistor T_{EM} may be a pulse width modulation signal that changes every frame, but embodiments of the present disclosure are not limited thereto.

A first electrode of the light emitting device ED may be connected to the second electrode of the light emitting transistor T_{EM}, and a second electrode of the light emitting device ED may be connected to ground. For example, the first electrode of the light emitting device ED may be an anode electrode, and the second electrode of the light emitting device ED may be a cathode electrode, but embodiments of the present disclosure are not limited thereto.

Each of the driving transistor T_{DR} and the light emitting transistor T_{EM} may be an n-type transistor or a p-type transistor.

The driving transistor T_{DR} may be turned on by the scan signal SC applied from a timing controller T-CON in the micro-driver (μDriver), and the light emitting transistor T_{EM} may be turned on by the light emitting signal EM. As a result, a driving current is applied to the light emitting device ED via the driving transistor T_{DR} and the light emitting transistor T_{EM} by the high potential power voltage VDD applied to the first electrode of the driving transistor T_{DR}, and thus the light emitting device ED may emit light.

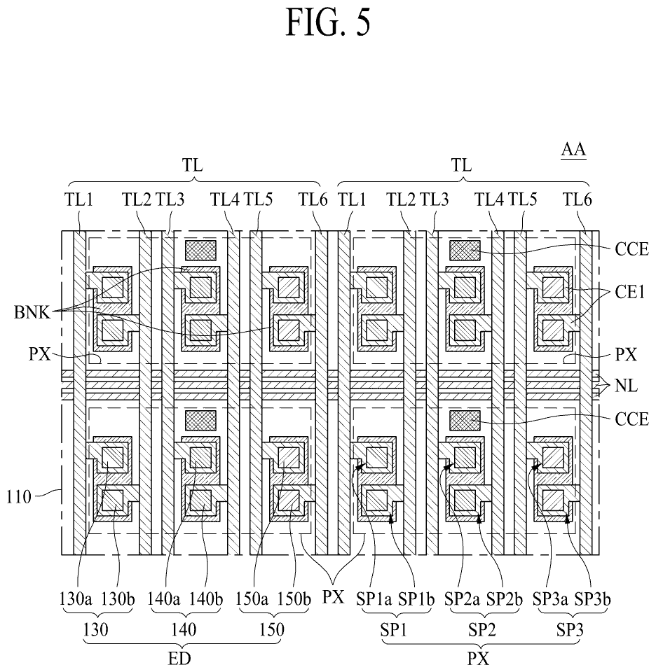

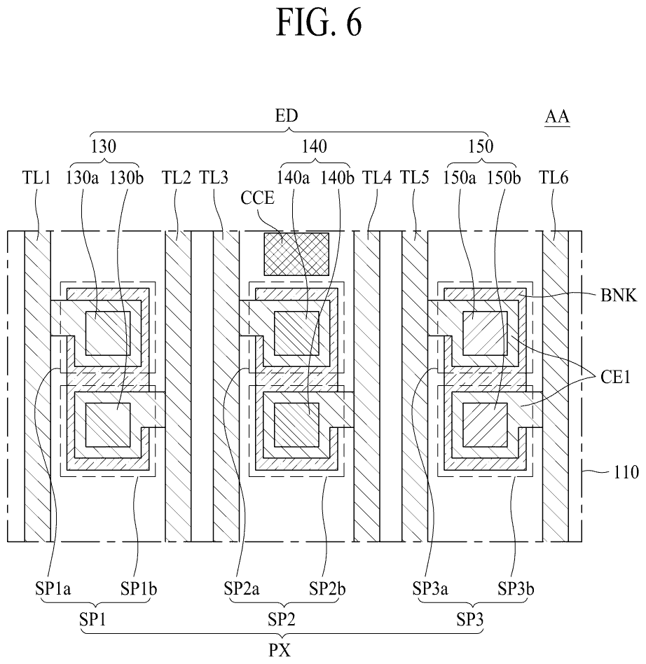

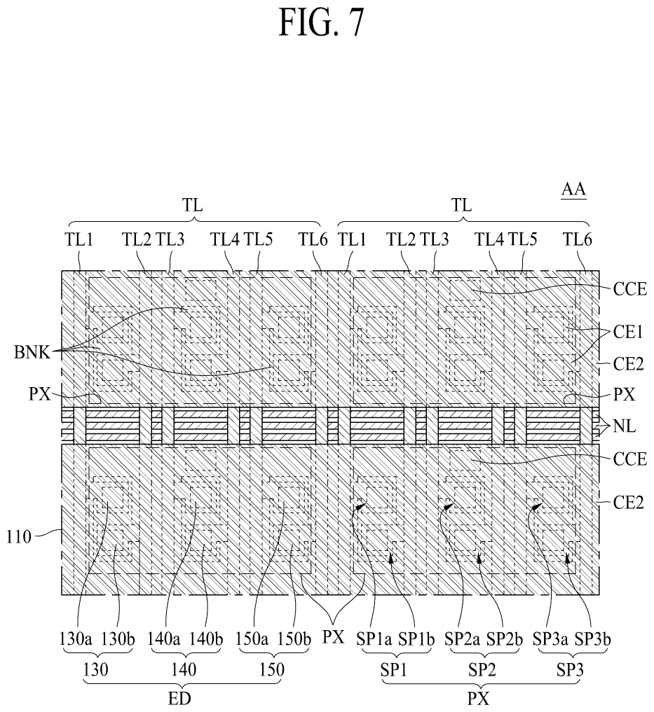

FIGS. 5 to 7 are plan views of a display device according to an embodiment of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. Although FIGS. 5 and 7 illustrate a plurality of signal lines TL, a plurality of communication lines NL, a plurality of first electrodes CE1, a plurality of banks BNK, and a plurality of light emitting devices ED, embodiments of the present disclosure are not limited thereto. FIG. 7 is an enlarged plan view in which the plurality of second electrodes CE2 are additionally disposed in FIG. 5, for convenience, an area overlapping the second electrodes CE2 is indicated by a dotted line.

Referring to FIGS. 5 to 7, a plurality of pixels PX including a plurality of sub-pixels may be disposed in the display area AA. Each of the plurality of sub-pixels includes a light emitting device ED and may independently emit light. The plurality of sub-pixels may be configured in a plurality of rows and a plurality of columns and may be disposed in a matrix form, but embodiments of the present disclosure are not limited thereto.

The plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, another may be a green sub-pixel, and the other may be a blue sub-pixel. Types of the plurality of sub-pixels are examples, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a 1-1th sub-pixel SP1a and a 1-2th sub-pixel SP1b. The pair of second sub-pixels SP2 may include a 2-1th sub-pixel SP2a and a 2-2th sub-pixel SP2b. The pair of third sub-pixels SP3 may include a 3-1th sub-pixel SP3a and a 3-2th sub-pixel SP3b. For example, one pixel PX may include the 1-1th sub-pixel SP1a, the 1-2th sub-pixel SP2a, the 2-1th sub-pixel SP2a, the 2-2th sub-pixel SP2b, the 3-1th sub-pixel SP3a, and the 3-2th sub-pixel SP3b, but embodiments of the present disclosure are not limited thereto.

The plurality of sub-pixels constituting one pixel PX may be variously arranged. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are examples, and embodiments of the present disclosure are not limited thereto.

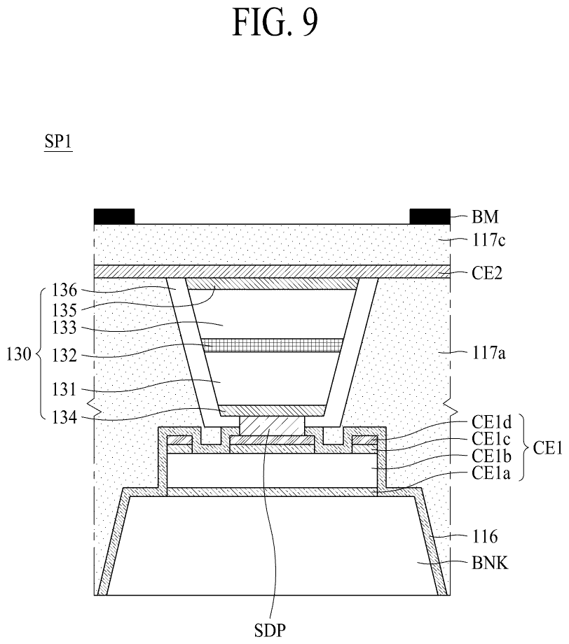

The plurality of signal lines TL may be disposed in an area between the plurality of sub-pixels. The plurality of signal lines TL may extend in a column direction between the plurality of sub-pixels. The plurality of signal lines TL may be lines that transmit the anode voltage from the pixel driving circuit PD (shown in FIG. 3) to the plurality of sub-pixels. For example, the plurality of signal lines TL may be electrically connected to the plurality of pixel driving circuits PD (shown in FIG. 3) and the first electrode CE1 of the plurality of sub-pixels. The anode voltage output from the pixel driving circuit PD (shown in FIG. 3) may be transmitted to the first electrode CE1 of the plurality of sub-pixels through the plurality of signal lines TL. For example, the first electrode CE1 may be an electrode electrically connected to the anode 134 of the light emitting device ED (shown in FIG. 9). Accordingly, the anode voltage from the signal line TL may be transmitted to the anode 134 of the light emitting device ED (shown in FIG. 9) through the first electrode CE1 Therefore, instead of forming a plurality of transistors and storage capacitors in each of the plurality of sub-pixels, a structure of the display device 1000 may be simplified by using a pixel driving circuit PD (shown in FIG. 3) in which the plurality of pixel circuits are integrated in one pixel driving circuit PD (shown in FIG. 3). In addition, since a circuit disposed in each of the plurality of sub-pixels is integrated in one pixel driving circuit PD (shown in FIG. 3), high efficiency and low power driving may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first sub-pixels SP1. The third signal line TL3 and the fourth signal line TL4 may be electrically connected to each of the pair of second sub-pixels SP2. Each of the fifth signal line TL5 and the sixth signal line TL6 may be electrically connected to each of the pair of third sub-pixels SP3.

The first signal line TL1 may be disposed at one side of the pair of first sub-pixels SP1, and the second signal line TL2 may be disposed at the other side of the pair of first sub-pixels SP1. The first signal line TL1 may be electrically connected to one of the pair of first sub-pixels SP1, for example, the first electrode CE1 of the 1-1th sub-pixel SP1a. The second signal line TL2 may be electrically connected to the remaining first sub-pixel SP1 of the pair of first sub-pixels SP1, for example, the first electrode CE1 of the 1-2th sub-pixel SP1b.

The third signal line TL3 may be disposed at one side of the pair of second sub-pixels SP2, and the fourth signal line TL4 may be disposed at the other side of the pair of second sub-pixels SP2. For example, the third signal line TL3 may be disposed adjacent to the second signal line TL2. The third signal line TL3 may be electrically connected to one of the pair of second sub-pixels SP2, for example, the first electrode CE1 of the 2-1th sub-pixel SP2a. The fourth signal line TL4 may be electrically connected to the remaining second sub-pixel SP2 of the pair of second sub-pixels SP2, for example, the first electrode CE1 of the 2-2th sub-pixel SP2b.

The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed adjacent to the fourth signal line TL4. The sixth signal line TL6 may be disposed adjacent to the first signal line TL1 connected to the adjacent pixel PX. The fifth signal line TL5 may be electrically connected to one of the pair of third sub-pixels SP3, for example, the first electrode CE1 of the 3-1th sub-pixel SP3a. The sixth signal line TL6 may be electrically connected to the remaining third sub-pixel SP3 of the pair of third sub-pixels SP3, for example, the first electrode CE1 of the 3-2th sub-pixel SP3b.

The plurality of signal lines TL may be formed of a conductive material. For example, the plurality of signal lines TL may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but embodiments of the present disclosure are not limited thereto. For another example, the plurality of signal lines TL may be formed of a multilayer structure of a conductive material. For example, the plurality of signal lines TL may be formed of the multilayer structure in which titanium (Ti), aluminum (Al), titanium (Ti), and indium tin oxide (ITO) are stacked, but embodiments of the present disclosure are not limited thereto.

The plurality of communication lines NL may be disposed in an area between the plurality of pixels PX. The plurality of communication lines NL may be disposed to extend in a row direction in an area between the plurality of pixels PX. The plurality of communication lines NL may be disposed in an area between the plurality of second electrodes CE2, and may not overlap the plurality of second electrodes CE2. For example, the plurality of communication lines NL may be wirings used for short-range communication such as near field communication (NFC). The plurality of communication lines NL may function as antennas. For example, the plurality of communication lines NL may be a plurality of connection lines, etc., but embodiments of the present disclosure are not limited thereto.

According to the present disclosure, banks BNK may be disposed in each of the plurality of sub-pixels. The plurality of banks BNK may be structures in which the plurality of light emitting devices ED are disposed. The plurality of banks BNK may guide positions of the plurality of light emitting devices ED in a transfer process of the plurality of light emitting devices ED. The plurality of light emitting devices ED may be transferred onto the plurality of banks BNK in the transfer process of the plurality of light emitting devices ED. The plurality of banks BNK may be bank patterns or construction, but embodiments of the present disclosure are not limited thereto.

The bank BNK of the first sub-pixel SP1, the bank BNK of the second sub-pixel SP2, and the bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated. Accordingly, the bank BNK of the first sub-pixel SP1, the second sub-pixel SP2, and the third sub-pixel SP3 to which different types of light emitting devices ED are transferred may be easily identified.

The bank BNK of the 1-1th sub-pixel SP1a and the bank BNK of the 1-2th sub-pixel SP1b may be connected to each other or may be spaced apart from each other. For example, the bank BNK of the 1-1st sub-pixel SP1a and the bank BNK of the 1-2th sub-pixel SP1b in which the same light emitting device ED is disposed may be connected, separated, or spaced apart from each other in consideration of design such as transfer process requirements. The bank BNK of the 2-1th sub-pixel SP2a and the bank BNK of the 2-2th sub-pixel SP2b may be connected to each other or may be spaced apart from each other. The bank BNK of the 3-1th sub-pixel SP3a and the bank BNK of the 3-2th sub-pixel SP3b may be connected to each other or may be spaced apart from each other. Accordingly, the bank BNK of the pair of first sub-pixels SP1, the bank BNK of the pair of second sub-pixels SP2, and the bank BNK of the pair of third sub-pixels SP3 may be variously formed, and embodiments of the present disclosure are not limited thereto.

For example, the plurality of banks BNK may be formed of an organic insulating material. The plurality of banks BNK may be formed of a single layer or a multilayer of an organic insulating material. For example, the plurality of banks BNK may be formed of a photo resist, a polyimide (PI), an acryl-based material, or the like, but embodiments of the present disclosure are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a portion of the first electrode CE1 may extend to an outside of the bank BNK to be electrically connected to the signal line TL closest to the first electrode CE1. For example, a portion of the first electrode CE1 of the 1-1th sub-pixel SP1a may extend to one side area of the 1-1th sub-pixel SP1a to be electrically connected to the first signal line TL1, and a portion of the first electrode CE1 of the 1-2th sub-pixel SP1b may extend to the other side area of the 1-2th sub-pixel SP1b to be electrically connected to the second signal line TL2. A portion of the first electrode CE1 of the 2-1th sub-pixel SP2a may extend to one side area of the 2-1th sub-pixel SP2a to be electrically connected to the third signal line TL3, and a portion of the first electrode CE1 of the 2-2th sub-pixel SP2b may extend to the other side area of the 2-2th sub-pixel SP2b to be electrically connected to the fourth signal line TL4. A portion of the first electrode CE1 of the 3-1th sub-pixel SP3a may extend to one side area of the 3-1th sub-pixel SP3a to be electrically connected to the fifth signal line TL5, and a portion of the first electrode CE1 of the 3-2th sub-pixel SP3b may extend to the other side area of the 3-2th sub-pixel SP3b to be electrically connected to the sixth signal line TL6.

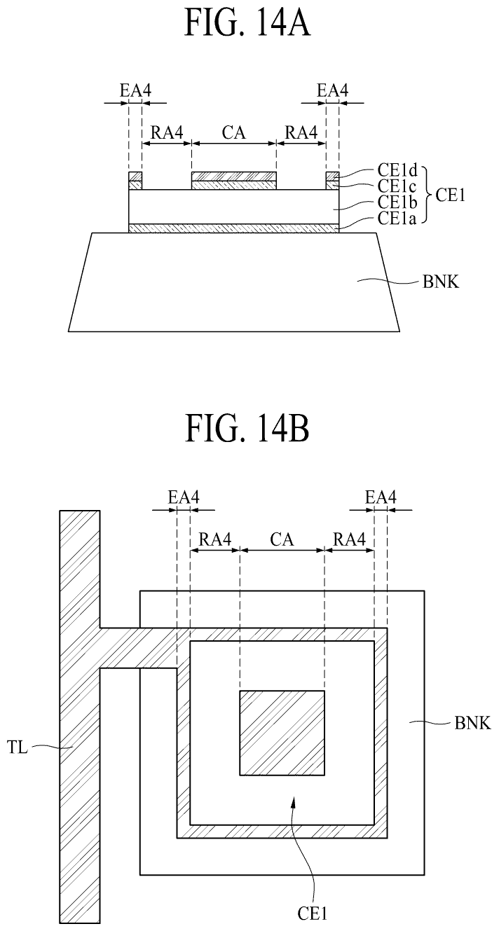

The first electrode CE1 is electrically connected to the anode electrode 134 (shown in FIG. 14) of the light emitting device ED. The anode voltage from the pixel driving circuit PD (shown in FIG. 3) may be transmitted to the light emitting device ED via the signal line TL and the first electrode CE1. Different voltages may be applied to the first electrode CE1 of each of the plurality of sub-pixels according to an image that is displayed. For example, different voltages may be applied to the first electrode CE1 of each of the plurality of sub-pixels. Accordingly, the first electrode CE1 may be a pixel electrode, and embodiments of the present disclosure are not limited thereto.

The first electrode CE1 may be formed of a conductive material. For example, the first electrode CE1 may be formed integrally with the plurality of signal lines TLs. For example, the first electrode CE1 may be formed of the same conductive material as the plurality of signal lines TLs, but embodiments of the present disclosure are not limited thereto. For example, the first electrode CE1 may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the first electrode CE1 may be formed of a multilayer structure of the conductive material. For example, the plurality of first electrodes CE1 may be formed of the multilayer structure in which titanium (Ti), aluminum (Al), titanium (Ti), and indium tin oxide (ITO) are stacked, but embodiments of the present disclosure are not limited thereto.

The light emitting device ED may be disposed in each of a plurality of sub-pixels. The plurality of light emitting device ED may be any one of a light-emitting diode (LED) and a micro light-emitting diode (Micro LED), but embodiments of the present disclosure are not limited thereto. The plurality of light emitting devices ED may be disposed on the bank BNK and the first electrode CE1. The plurality of light emitting devices ED may be disposed on the first electrode CE1 and may be electrically connected to the first electrode CE1. Accordingly, the light emitting device ED may emit light by receiving the anode voltage from the pixel driving circuit PD through the signal line TL and the first electrode CE1.

The plurality of light emitting devices ED may include a first light emitting device 130, a second light emitting device 140, and a third light emitting device 150. The first light emitting device 130 may be disposed in the first sub-pixel SP1. The second light emitting device 140 may be disposed in the second sub-pixel SP2. The third light emitting device 150 may be disposed in the third sub-pixel SP3. For example, one of the first light emitting device 130, the second light emitting device 140, and the third light emitting device 150 may be a red light emitting device, another may be a green light emitting device, and the other may be a blue light emitting device, but embodiments of the present disclosure are not limited thereto. Accordingly, light of various colors including white may be implemented by combining red light, green light, and blue light emitted from the plurality of light emitting devices ED. Types of the plurality of light emitting devices ED are examples, and embodiments of the present disclosure are not limited thereto.

The first light emitting device 130 may include a 1-1th light emitting device 130a disposed in the 1-1th sub-pixel SP1a and a 1-2th light emitting device 130b disposed in the 1-2th sub-pixel SP1b. The second light emitting device 140 may include a 2-1th light emitting device 140a disposed in the 2-1th sub-pixel SP2a and a 2-2th light emitting device 140b disposed in the 2-2th sub-pixel SP2b. The third light emitting device 150 may include a 3-1th light emitting device 150a disposed in the 3-1th sub-pixel SP3a and a 3-2th light emitting device 150b disposed in the 3-2th sub-pixel SP3b.

The second electrode CE2 may be disposed in each of the plurality of sub-pixels. The second electrode CE2 may be disposed on the light emitting device ED. The second electrode CE2 may be electrically connected to the pixel driving circuit PD (shown in FIG. 3) through a plurality of contact electrodes CCE.

For example, the second electrode CE2 may be electrically connected to the cathode electrode 135 (shown in FIG. 14) of the light emitting device ED to transmit the cathode voltage from the pixel driving circuit PD (shown in FIG. 3) to the light emitting device ED. The same cathode voltage may be applied to the second electrode CE2 of each of the plurality of sub-pixels. For example, the same voltage may be applied to the second electrode CE2 of each of the plurality of sub-pixels and the cathode electrode 135 (shown in FIG. 9) of the light emitting device ED. Accordingly, the second electrode CE2 may be a common electrode, but embodiments of the present disclosure are not limited thereto.

At least some of the plurality of sub-pixels may share the second electrode CE2. Some of the second electrodes CE2 of each of the plurality of sub-pixels may be integrally formed to be electrically connected. When the same voltage is applied to the second electrode CE2, the second electrode CE2 of some of the sub-pixels may be shared and used. For example, the second electrodes CE2 of some of the pixels PX arranged in the same row in the horizontal direction may be integrally formed and connected to each other. For example, one second electrode CE2 may be disposed in the plurality of pixels PX. One second electrode CE2 may be disposed in every n sub-pixels.

For example, some of the second electrodes CE2 of each of the plurality of sub-pixels may be spaced apart from each other or to be separated from each other. For example, the second electrode CE2 connected to the pixels PX of the n-th row and the second electrode CE2 connected to the pixels PX of the n+1th row may be spaced apart from each other. For example, the plurality of second electrodes CE2 may be spaced apart from each other with the plurality of communication lines NL extending in a row direction interposed therebetween. Accordingly, the number of the plurality of sub-pixels may be greater than the number of the plurality of second electrodes CE2. For another example, all of the second electrodes CE2 of the plurality of sub-pixels may be integrally connected so that only one second electrode CE2 may be disposed on the substrate 110, and embodiments of the present disclosure are not limited thereto.

The plurality of second electrodes CE2 may be formed of a transparent conductive material, but embodiments of the present disclosure are not limited thereto. The plurality of second electrodes CE2 may be formed of the transparent conductive material so that light emitted from the light emitting device ED is directed to an upper portion of the second electrode CE2. For example, the second electrode CE2 may be formed of the transparent conductive material such as indium tin oxide (ITO), indium zinc oxide (IZO), indium gallium zinc oxide (IGZO), or the like, but embodiments of the present disclosure are not limited thereto.

A plurality of contact electrodes CCE may be disposed on the substrate 110. For example, the plurality of contact electrodes CCE may be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD (shown in FIG. 3) to the second electrode CE2.

For example, when a micro-LED is used as the light emitting device ED, a plurality of micro-LEDs may be formed in a wafer and the micro-LEDs may be transferred to the substrate 110 to manufacture the display panel 100. Various defects may occur in the process of transferring the plurality of light emitting devices ED having a micro size from the wafer to the substrate 110. For example, a non-transmission defect in which the light emitting device ED is not transferred may occur in some sub-pixels, and a defect in which the light emitting device ED is transferred out of a correct position due to an alignment error may occur in some sub-pixels. Also, the transfer process has proceeded normally, but the transferred light emitting device ED itself may be a defect. Accordingly, the plurality of the same light emitting devices ED may be transferred to one sub-pixel in consideration of the defect during the transfer process of the plurality of light emitting devices ED. After the lighting test of the plurality of light emitting devices ED is performed, only one light emitting device ED finally determined to be normal may be used.

For example, the 1-1th light emitting device 130a and the 1-2th light emitting device 130b may be transferred to one pixel PX, and it is possible to inspect whether there is a defect in the 1-1th light emitting device 130a and the 1-2th light emitting device 130b. If both of the 1-1th light emitting device 130a and the 1-2th light emitting device 130b are determined to be normal, only the 1-1th light emitting device 130b may be used and the 1-2th light emitting device 130b may be not used. As another example, if only the 1-2th light emitting device 130b of the 1-1th light emitting device 130a and the 1-2th light emitting device 130b is determined to be normal, the 1-1th light emitting device 130a may not be used and only the 1-2th light emitting device 130b may be used. Therefore, even if the plurality of the same light emitting devices ED are transferred to one pixel PX, only one light emitting device ED may be finally used.

Accordingly, any one of the pair of light emitting devices ED may be a main or primary light emitting device ED, and the other light emitting device ED may be a redundancy light emitting device ED. The redundancy light emitting device ED may be an extra light emitting device ED transferred to prepare for a defect in the main light emitting device ED. When the main light emitting device ED is defective, the redundancy light emitting device ED may be used instead of the main light emitting device ED. Accordingly, the main light emitting device ED and the redundancy light emitting device ED are transferred to one pixel PX, thereby minimizing deterioration of display quality due to defects in the main light emitting device ED and the redundancy light emitting device ED.

For example, the 1-1th light emitting device 130a, the 2-1th light emitting device 140a, and the 3-1th light emitting device 150a transferred to one pixel PX may be used as the main light emitting device ED, and the 1-2th light emitting device 130b, the 2-2th light emitting device 140b, and the 3-2th light emitting device 150b may be used as the redundancy light emitting device ED.

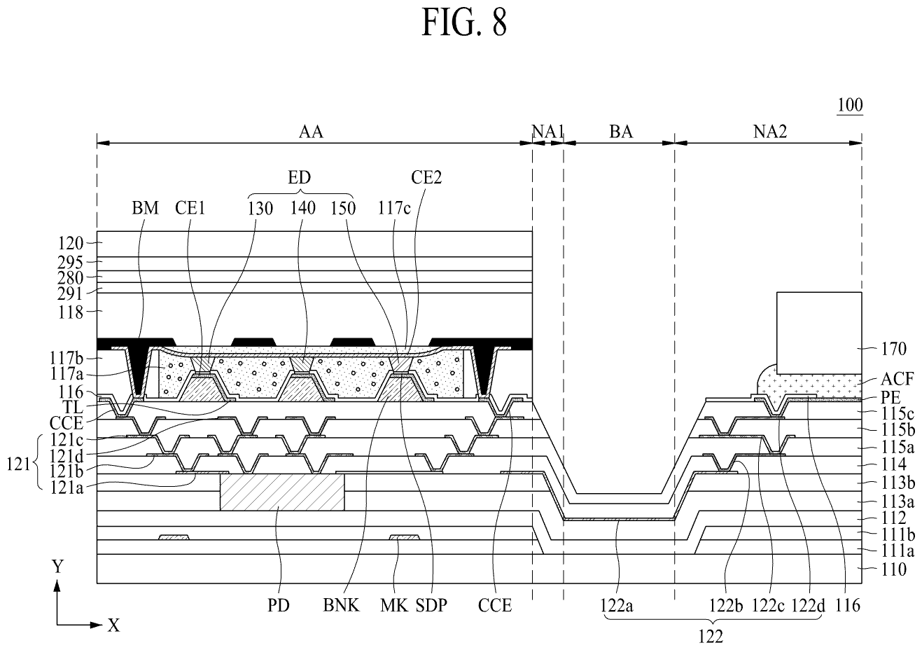

FIG. 8 is a cross-sectional view of a display device according to an embodiment of the present disclosure. And, FIG. 9 is a cross-sectional view of a display device according to an embodiment of the present disclosure. For example, FIG. 8 is a cross-sectional view of the display area AA, the first non-display area NA, the bending area BA, and the second non-display area NA2, and FIG. 9 is a cross-sectional view of a portion of the display area AA.

Referring to FIG. 8, a first buffer layer 111a and a second buffer layer 111b may be disposed in the remaining area of the substrate 110 except the bending area BA.

The first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be formed of a single layer or a multilayer composed of silicon oxide (SiOx) or silicon nitride (SiNx), but embodiments of the present disclosure are not limited thereto.

For example, portions of the first buffer layer 111a and the second buffer layer 111b on the bending area BA may be removed. An upper surface of the substrate 110 disposed in the bending area BA may be exposed by the first buffer layer 111a and the second buffer layer 111b. The first buffer layer 111a and the second buffer layer 111b made of the inorganic insulating material may be removed from the bending area BA, thereby minimizing cracks in the first buffer layer 111a and the second buffer layer 111b that may occur during bending.

A plurality of alignment keys MK may be disposed between the first buffer layer 111a and the second buffer layer 111b. The plurality of alignment keys MK may be identify a position of the pixel driving circuit PD during a manufacturing process of the display panel 100. For example, the plurality of alignment keys MK may align the position of the pixel driving circuit PD transferred onto an adhesive layer 112. For another example, the plurality of alignment keys MK may be omitted.

An adhesive layer 112 may be disposed on the second buffer layer 111b. The adhesive layer 112 may be disposed in the display area AA, the first non-display area NA1, the bending area BA, and the second non-display area NA2. For another example, a portion of the adhesive layer 112 may be removed from the non-display area NA including the bending area BA. For example, the adhesive layer 112 may be formed of any one of an Adhesive polymer, an epoxy resin, a UV curable resin, a polyimide-based resin, an acrylate-based material, a urethane-based material, and a polydimethylsiloxane (PDMS), but embodiments of the present disclosure are not limited thereto.

In the display area AA, the pixel driving circuit PD may be disposed on the adhesive layer 112. When the pixel driving circuit PD is implemented as a driving driver, the driving driver may be mounted on the adhesive layer 112 through a transfer process, but embodiments of the present disclosure are not limited thereto.

A first protective layer 113a and a second protective layer 113b may be disposed on the adhesive layer 112 and the pixel driving circuit PD. The first protective layer 113a and the second protective layer 113b may surround a side surface of the pixel driving circuit PD, but embodiments of the present disclosure are not limited thereto. For example, the second protective layer 113b may cover at least a portion of a upper surface of the pixel driving circuit PD. For example, at least one of the first protective layer 113a and the second protective layer 113b disposed on the bending area BA may be omitted. For example, the first protective layer 113a is entirely disposed in the display area AA and the non-display area NA, and the second protective layer 113b is partially disposed in the display area AA, the first non-display area NA1, and the second non-display area NA2 and may not be disposed in the bending area BA. For example, a portion of the second protective layer 113b in the bending area BA may be removed. However, embodiments of the present disclosure are not limited thereto.

The first protective layer 113a and the second protective layer 113b may be formed of an organic insulating material, but embodiments of the present disclosure are not limited thereto. For example, the first protective layer 113a and the second protective layer 113b may be formed of a photo resist, polyimide (PI), a photoacryl-based material, or the like, but embodiments of the present disclosure are not limited thereto. For example, the first protective layer 113a and the second protective layer 113b may be an overcoating layer or an insulating layer, but embodiments of the present disclosure are not limited thereto.

According to the present disclosure, a plurality of first connection lines 121 may be disposed on the second protective layer 113b in the display area AA. The plurality of first connection lines 121 may be wirings for electrically connecting the pixel driving circuit PD to other elements. For example, the pixel driving circuit PD may be electrically connected to the plurality of signal lines TL, the plurality of contact electrodes CCE, and the like through the plurality of first connection lines 121. For example, the plurality of first connection lines 121 may include a plurality of 1-1th connection lines 121a, a plurality of 1-2th connection lines 121b, a plurality of 1-3th connection lines 121c, and a plurality of 1-4th connection lines 121d, but embodiments of the present disclosure are not limited thereto.

For example, the plurality of 1-1th connection lines 121a may be disposed on the second protective layer 113b. The plurality of 1-1th connection lines 121a may be electrically connected to the pixel driving circuit PD. The plurality of 1-1th connection lines 121a may transmit voltages output from the pixel driving circuit PD to the first electrode CE1 or the second electrode CE2.

For example, a third protective layer 114 may be disposed on the second protective layer 113b. The third protective layer 114 may be disposed on the entire display area AA and the non-display area NA. In the bending area BA, the third protective layer 114 may disposed on or cover a side surface of the second protective layer 113b and an upper surface of the first protective layer 113a. The third protective layer 114 may be formed of an organic insulating material. For example, the third protective layer 114 may be formed of a photo resist, polyimide (PI), a photoacryl-based material, or the like, but embodiments of the present disclosure are not limited thereto. For example, the first protective layer 113a, the second protective layer 113b, and the third protective layer 114 may be formed of the same material, but embodiments of the present disclosure are not limited thereto.

The plurality of 1-2th connection lines 121b may be disposed on the third protective layer 114. The plurality of 1-2th connection lines 121b may be connected to the pixel driving circuit PD through the 1-1th connection lines 121a or may be directly connected to the pixel driving circuit PD. For example, a portion of the 1-2th connection line 121b may be directly connected to the pixel driving circuit PD through a contact hole of the third protective layer 114. The other portion of the 1-2th connection line 121b may be electrically connected to the 1-1th connection line 121a through a contact hole of the third protective layer 114. However, embodiments of the present disclosure are not limited thereto. For example, the voltage output from the pixel driving circuit PD may be transmitted to the first electrode CE1 or the second electrode CE2 through connection lines different from the plurality of 1-2th connection lines 121b.

A first insulating layer 115a may be disposed on the plurality of 1-2th connection lines 121b. The first insulating layer 115a may be disposed in the entire display area AA and the non-display area NA, but embodiments of the present disclosure are not limited thereto. The first insulating layer 115a may be formed of an organic insulating material, but embodiments of the present disclosure are not limited thereto. For example, the first insulating layer 115a may be formed of a photo resist, polyimide (PI), a photoacryl-based material, or the like, but embodiments of the present disclosure are not limited thereto.

The plurality of 1-3th connection lines 121c may be disposed on the first insulating layer 115a. The plurality of 1-3th connection lines 121c may be electrically connected to the plurality of 1-2th connection lines 121b. For example, the 1-3th connection lines 121c may be electrically connected to the 1-2th connection lines 121b through a contact hole of the first insulating layer 115a.

A second insulating layer 115b may be disposed on the plurality of 1-3th connection lines 121c. The second insulating layer 115b may be disposed in the remaining area except for the bending area BA, but embodiments of the present disclosure are not limited thereto. The second insulating layer 115b may be disposed in the display area AA, the first non-display area NA1, and the second non-display area NA2, but embodiments of the present disclosure are not limited thereto. For example, at least a portion of the second insulating layer 115b disposed in the bending area BA may be removed. The second insulating layer 115b may be formed of an organic insulating material, but embodiments of the present disclosure are not limited thereto. For example, the second insulating layer 115b may be formed of a photo resist, polyimide (PI), a photoacryl-based material, or the like, but embodiments of the present disclosure are not limited thereto.

The plurality of 1-4th connection lines 121d may be disposed on the second insulating layer 115b. The plurality of 1-4th connection lines 121d may be electrically connected to the plurality of 1-3th connection lines 121c. For example, the 1-4th connection lines 121d may be electrically connected to the 1-3th connection lines 121c through a contact hole of the second insulating layer 115b.

The 1-4th connection line 121d may be connected to the contact electrode CCE through a contact hole of the third insulating layer 115c. Accordingly, the contact electrode CCE and the pixel driving circuit PD may be electrically connected to each other by the first connection line 121.

Although not shown, the 1-4th connection line 121d may be directly connected to the signal line TL through a contact hole disposed in the third insulating layer 115c, or may be electrically connected to the signal line TL through other additional lines or electrodes. Accordingly, the signal line TL and the pixel driving circuit PD may be electrically connected by the first connection line 121.

According to the present disclosure, a plurality of second connection lines 122 may be disposed on the second protective layer 113b in the non-display area NA. The plurality of second connection lines 122 may be wirings for transmitting a signal received from the flexible circuit board (or a flexible film) 170 (shown in FIG. 2) and a printed circuit board 160 (shown in FIG. 2) to the pixel driving circuit PD of the display area AA.

For example, the plurality of second connection lines 122 may be electrically connected to the plurality of pad electrodes PE to receive signals from flexible circuit boards (or flexible films) 170 (shown in FIG. 2) and printed circuit boards 160 (shown in FIG. 2).

For example, the plurality of second connection lines 122 may extend from the pad part PAD (shown in FIG. 2) toward the display area AA to transmit signals to the wirings of the display area AA. In this case, the plurality of second connection lines 122 may function as link lines LL (shown in FIG. 3). The plurality of second connection lines 122 may include a 2-1th connection line 122a, a 2-2th connection line 122b, a 2-3th connection line 122c, and a 2-4th connection line 122d.

The plurality of 2-1th connection lines 122a may be disposed on the second protective layer 113b. The plurality of 2-1th connection lines 122a may extend from the second non-display area NA2 to the bending area BA and the first non-display area NA1. The plurality of 2-1 connection lines 122a may transmit signals received from the flexible circuit board (or flexible film 170) (shown in FIG. 2) and the printed circuit board 160 (shown in FIG. 2) to the pixel driving circuit PD of the display area AA. Accordingly, the plurality of 2-1th connection lines 122a may be electrically connected to the pad electrode PE and the pixel driving circuit PD, respectively.

For example, although not shown, the 2-1th connection line 122a may extend to the display area AA to be directly connected to the pixel driving circuit PD in the display area AA, or may be electrically connected to the pixel driving circuit PD through other additional line or electrodes. In addition, the 2-1th connection line 122a may be electrically connected to the pad electrode PE in the second non-display area NA2 via the 2-2th connection line 122b, the 2-3th connection line 122c, and the 2-4th connection line 122d. Accordingly, the pixel driving circuit PD and the pad electrode PE may be electrically connected to each other by the second connection line 122.

The plurality of 2-2th connection lines 122b may be disposed on the third protective layer 114. The plurality of 2-2th connection lines 122b may be disposed in the second non-display area NA2. The 2-2 connection lines 122b may be electrically connected to the 2-1th connection lines 122a through a contact hole of the third protective layer 114. Therefore, signals from the flexible circuit board (or flexible film) 170 (shown in FIG. 2) and the printed circuit board 160 (shown in FIG. 2) may be transmitted to the 2-1 connection lines 122a through the 2-2 connection lines 122b.

The 2-3th connection line 122c may be disposed on the first insulating layer 115a. The 2-3th connection line 122c may be disposed in the second non-display area NA2. The 2-3th connection line 122c may be electrically connected to the 2-2th connection line 122b through a contact hole of the first insulating layer 115a. Accordingly, signals from the flexible circuit board (or flexible film) 170 (shown in FIG. 2) and the printed circuit board 160 (shown in FIG. 2) may be transmitted to the 2-1th connection line 122a through the 2-3th connection line 122c and the 2-2th connection line 122b.

The 2-4th connection line 122d may be disposed on the second insulating layer 115b. The 2-4th connection line 122d may be disposed in the second non-display area NA2. The 2-4th connection line 122d may be electrically connected to the 2-3th connection line 122c through a contact hole of the second insulating layer 115b. The 2-4th connection line 122d may be electrically connected to the pad electrode PE through a contact hole of the third insulating layer 115c.

Accordingly, signals from the flexible circuit board (or flexible film) 170 (shown in FIG. 2) and the printed circuit board 160 (shown in FIG. 2) may be transmitted to the 2-1th connection line 122a through the 2-4th connection line 122d, the 2-3th connection line 122c, and the 2-2 connection line 122b.

The plurality of first connection lines 121 and the plurality of second connection lines 122 may be formed of a conductive material having excellent ductility or various conductive materials used in the display area AA. For example, the second connection line 122 partially disposed in the bending area BA may be formed of a conductive material having excellent ductility, such as gold (Au), silver (Ag), or aluminum (Al), but embodiments of the present disclosure are not limited thereto. For another example, the plurality of first connection lines 121 and a plurality of second connection lines 122 may be formed of molybdenum (Mo), chromium (Cr), titanium (Ti), nickel (Ni), neodymium (Nd), copper (Cu), an alloy of silver (Ag) and magnesium (Mg), or an alloy thereof, but embodiments of the present disclosure are not limited thereto.

A third insulating layer 115c may be disposed on the plurality of first connection lines 121 and the plurality of second connection lines 122. The third insulating layer 115c may be disposed in the remaining area except for the bending area BA, but embodiments of the present disclosure are not limited thereto. The third insulating layer 115c may be disposed in the display area AA, the first non-display area NA1, and the second non-display area NA2. At least a portion of the third insulating layer 115c in the bending area BA may be removed. The third insulating layer 115c may be formed of an organic insulating material, but embodiments of the present disclosure are not limited thereto. For example, the third insulating layer 115c may be formed of a photo resist, polyimide (PI), a photo acryl-based material, or the like, but embodiments of the present disclosure are not limited thereto.

A plurality of banks BNK may be disposed on the third insulating layer 115c in the display area AA. The plurality of banks BNK may overlap each of the plurality of sub-pixels. The plurality of banks BNK may not be disposed in the first non-display area NA1, the second non-display area NA2, and the bending area BA. One or more light emitting devices ED of the same type may be disposed on an upper portion of each of the plurality of banks BNK.

In the display area AA, a plurality of signal lines TLs may be disposed on the third insulating layer 115c. The plurality of signal lines TLs may be disposed between the plurality of banks BNK. For example, the plurality of signal lines TLs may be disposed adjacent to any one of the plurality of banks BNK. Each of the plurality of signal lines TLs may be electrically connected to the first connection line 121, for example, the 1-4th connection line 121d.

A plurality of contact electrodes CCE may be disposed on the third insulating layer 115c in the display area AA. The plurality of contact electrodes CCE may supply the cathode voltage from the pixel driving circuit PD to the second electrode CE2. Each of the plurality of contact electrodes CCE may be electrically connected to the first connection line 121, for example, the 1-4th connection line 121d.

A first electrode CE1 may be disposed on the bank BNK. For example, the first electrode CE1 may extend from the adjacent signal line TL to an upper portion of the bank BNK. The first electrode CE1 may be disposed on an upper surface of the bank BNK and a side surface of the bank BNK. For example, the first electrode CE1 may extend from the signal line TL on an upper surface of the third insulating layer 115c to the side surface of the bank BNK and the upper surface of the bank BNK. The first electrode CE1 may be integrally formed with the signal line TL.

Referring to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d, but embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but embodiments of the present disclosure are not limited thereto.

According to the present disclosure, some of the plurality of conductive layers included in the first electrode CE1 having high reflection efficiency may be composed of an alignment key and/or a reflector for aligning the light emitting device ED. For example, the second conductive layer CE1b among the plurality of conductive layers of the first electrode CE1 may include a reflective material. For example, the second conductive layer CE1b may include aluminum (Al), but embodiments of the present disclosure are not limited thereto. Thus, the second conductive layer CE1b may be used as a reflective plate. Also, due to a high reflection efficiency of the second conductive layer CE1b, identification may be easily performed in a manufacturing process, and thus an arrangement position or a transfer position of the light emitting device ED with respect to the second conductive layer CE1b.

For example, in order to use the second conductive layer CE1b as the reflective plate, the third conductive layer CE1c and the fourth conductive layer CE1d covering the second conductive layer CE1b may be partially removed or etched. For example, portions of the third and fourth conductive layers CE1c and CE1d disposed on the bank BNK may be removed or etched to expose an upper surface of the second conductive layer CE1b. For example, a central portion and an edge portion of the third and fourth conductive layers CE1c and CE1d on which a solder pattern SDP is disposed may remain, and remaining portions except for the center portion of the third and fourth conductive layers CE1c and CE1d may be removed. For example, the central portion and the edge portion of each of the third conductive layer CE1c made of titanium (Ti) and the fourth conductive layer CE1d made of indium tin oxide (ITO) may not be etched. Thus, another conductive layer of the first electrode CE1 may be prevented from being corroded by a TMAH (Tetra Methyl Ammonium Hydroxide) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has high adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

As shown in FIGS. 8 and 9, according to the present disclosure, the signal line TL, the contact electrode CCE, and the pad electrode PE disposed on the same layer as the first electrode CE1 may be formed of multiple layers of conductive materials, but embodiments of the present disclosure are not limited thereto. For example, the signal line TL, the contact electrode CCE, and the pad electrode PE may be formed of multiple layers in which indium tin oxide (ITO), titanium (Ti), aluminum (Al), and titanium (Ti) are stacked, but embodiments of the present disclosure are not limited thereto.

According to the present disclosure, a solder pattern SDP may be disposed on the first electrode CE1 in each of the plurality of sub-pixels. The solder pattern SDP may bond the light emitting device ED to the first electrode CE1. The first electrode CE1 and the light emitting device ED may be electrically connected to each other through eutectic bonding using the solder pattern SDP, but embodiments of the present disclosure are not limited thereto. For example, when the solder pattern SDP is formed of indium (In), and the anode electrode 134 of the light emitting device ED is formed of gold (Au), the solder pattern SDP and the anode electrode 134 may be bonded to each other by applying heat and pressure in the transfer process of the light emitting device ED. The light emitting device ED may be bonded to the solder pattern SDP and the first electrode CE1 without a separate adhesive member through eutectic bonding. For example, the solder pattern SDP may be formed of indium (In), tin (Sn), or alloys thereof, but embodiments of the present disclosure are not limited thereto. For example, the solder pattern SDP may be a bonding pad, a contact pad, or the like, but embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE may be removed in the second non-display area NA2. A portion of the passivation layer 116 covering the plurality of contact electrodes CCE may be removed in the display area AA. The passivation layer 116 covering the solder pattern SDP may be removed in the display area AA.

Since the passivation layer 116 covers the remaining areas while exposing a portion of the plurality of pad electrodes PE, a portion of the plurality of contact electrodes CCE and a portion of the solder pattern SDP, penetration of moisture or impurities flowing into the light emitting device ED may be reduced. For example, the passivation layer 116 may be formed of a single layer or multiple layers including silicon oxide (SiOx) or silicon nitride (SiNx), but embodiments of the present disclosure are not limited thereto. For example, the passivation layer 116 may be a protective layer or an insulating layer, but embodiments of the present disclosure are not limited thereto. For example, the passivation layer 116 may include a hole exposing the solder pattern SDP and a hole exposing the contact electrode CCE.

In each of the plurality of sub-pixels, the light emitting device ED may be disposed on the solder pattern SDP. The first light emitting device 130 may be disposed in the first sub-pixel SP1. The second light emitting device 140 may be disposed in the second sub-pixel SP2. The third light emitting device 150 may be disposed in the third sub-pixel SP3.

The light emitting device ED may be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

Referring to FIG. 9, the first light emitting device 130 may include an anode 134, a first semiconductor layer 131, an active layer 132, a second semiconductor layer 133, a cathode 135, and an encapsulation layer 136, but embodiments of the present disclosure are not limited thereto. For example, the encapsulation layer 136 may not be included in the first light emitting device 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may include a compound semiconductor such as a group III-V or a group II-VI, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but embodiments of the present disclosure are not limited thereto. For example, At least one of the first semiconductor layer 131 and the second semiconductor layer 133 may be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenic (AlGaAs), or a material such as gallium arsenic (GaAs), but embodiments of the present disclosure are not limited thereto. For example, the n-type impurity may be silicon (Si), germanium (Ge), selenium (Se), carbon (C), tellurium (Te), tin (Sn), or the like, but embodiments of the present disclosure are not limited thereto. For example, the p-type impurity may be magnesium (Mg), zinc (Zn), calcium (Ca), strontium (Sr), barium (Ba), beryllium (Be), or the like, but embodiments of the present disclosure are not limited thereto.

For example, each of the first semiconductor layer 131 and the second semiconductor layer 133 may be a nitride semiconductor including the n-type impurity and a nitride semiconductor including the p-type impurity, but embodiments of the present disclosure are not limited thereto. For example, the first semiconductor layer 131 may be a nitride semiconductor including the p-type impurity, and the second semiconductor layer 133 may be a nitride semiconductor including the n-type impurity, but embodiments of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may be formed of one of a single well structure, a multi-well structure, a single quantum well structure, a multi-quantum well (MQW) structure, a quantum dot structure, and a quantum line structure, but embodiments of the present disclosure are not limited thereto. For example, the active layer 132 may be formed of indium gallium nitride (InGaN), or gallium nitride (GaN), but embodiments of the present disclosure are not limited thereto.

For another example, the active layer 132 may include a multi-quantum well (MQW) structure having a well layer and a barrier layer having a band gap higher than that of the well layer. For example, the active layer 132 may include InGaN as a well layer, and may include an AlGaN layer as a barrier layer, but embodiments of the present disclosure are not limited thereto.

The anode 134 may be disposed between the first semiconductor layer 131 and the solder pattern SDP. For example, the anode 134 may electrically connect the first semiconductor layer 131 to the first electrode CE1. The anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but embodiments of the present disclosure are not limited thereto. For example, the anode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or alloys thereof, but embodiments of the present disclosure are not limited thereto.

The cathode 135 may be disposed on the second semiconductor layer 133. For example, the cathode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light emitting device ED to be directed to an upper portion of the light emitting device ED, but embodiments of the present are not limited thereto. For example, the cathode 135 may be formed of a material such as indium tin oxide (ITO), indium zinc oxide (IZO), indium gallium zinc oxide (IGZO), or the like, but embodiments of the present disclosure are not limited thereto.

The encapsulation layer 136 may be disposed on at least a portion of each of the first semiconductor layer 131, the active layer 132, the second semiconductor layer 133, the anode 134, and the cathode 135. For example, the encapsulation layer 136 may surround at least a portion of each of the first semiconductor layer 131, the active layer 132, the second semiconductor layer 133, the anode 134, and the cathode 135.

For example, the encapsulation layer 136 may protect the first semiconductor layer 131, the active layer 132, and the second semiconductor layer 133. For example, the encapsulation layer 136 may be disposed on a side surface of the first semiconductor layer 131, a side surface of the active layer 132, and a side surface of the second semiconductor layer 133.

For example, the encapsulation layer 136 may be disposed on at least a portion of the anode 134 and the cathode 135, for example, on the edge portion (or one side) of the anode 134 and the edge portion (or one side) of the cathode 135. At least a portion of the anode 134 may be exposed by the encapsulation layer 136, and the anode 134 may connect with the solder pattern SDP. For example, at least a portion of the cathode 135 may be exposed by the encapsulation layer 136 and the cathode 135 may connect with the second electrode CE2. For example, the encapsulation layer 136 may be formed of an insulating material such as silicon nitride (SiNx) or silicon oxide (SiOx), but embodiments of the present disclosure are not limited thereto.

For another example, the encapsulation layer 136 may have a structure in which a reflective material is distributed in a resin layer, but embodiments of the present disclosure are not limited thereto. For example, the encapsulation layer 136 may be manufactured as a reflector having various structures, but embodiments of the present disclosure are not limited thereto. Light emitted from the active layer 132 may be reflected upward by the encapsulation layer 136 so that light extraction efficiency may be improved. For example, the encapsulation layer 136 may be a reflective layer, but embodiments of the present disclosure are not limited thereto.

According to the present disclosure, the light emitting device ED has been described as a vertical structure, but embodiments of the present disclosure are not limited thereto. For example, the light emitting device ED may have a lateral structure or a flip chip structure.

Although the first light emitting device 130 has been described with reference to FIG. 9, the second light emitting device 140 and the third light emitting device 150 may have substantially the same structure as the first light emitting device 130. For example, the second light emitting device 140 and the third light emitting device 150 may have substantially the same configuration as the first semiconductor layer 131, the active layer 132, the second semiconductor layer 133, the anode 134, the cathode 135, and the encapsulation layer 136.

As shown in FIGS. 8 and 9, a first optical layer 117a surrounding the plurality of light emitting devices ED may be disposed in the display area AA. For example, the first optical layer 117a may cover the side surfaces of the plurality of light emitting devices ED and the side surfaces of the plurality of banks BNK in the plurality of sub-pixels. For example, the first optical layer 117a may cover a portion of the passivation layer 116. For example, the first optical layer 117a may cover the second electrode CE2, a portion of the passivation layer 116, and an area between the plurality of light emitting devices ED. The first optical layer 117a may be disposed or covered between the plurality of light emitting devices ED and between the plurality of banks BNK included in one pixel PX. For example, the first optical layer 117a may extend in the first direction X, and the plurality of first optical layers 117a may be spaced apart from each other in the second direction Y in a plan view. For example, the first optical layer 117a may be disposed between the passivation layer 116 and the second electrode CE2 to surround the side surface of the light emitting device ED and the side surface of the bank BNK, but embodiments of the present disclosure are not limited thereto. For example, the first optical layer 117a may be a diffusion layer, a sidewall diffusion layer, or the like, but embodiments of the present disclosure are not limited thereto.

The first optical layer 117a may include an organic insulating material in which fine particles are distributed, but embodiments of the present disclosure are not limited thereto. For example, the first optical layer 117a may be formed of siloxane in which fine metal particles such as titanium dioxide (TiO₂) particles are distributed, but embodiments of the present disclosure are not limited thereto. Light from the plurality of light emitting devices ED may be scattered by fine particles distributed in the first optical layer 117a and emitted to an outside of the display panel 100. Accordingly, the first optical layer 117a may improve extraction efficiency of light emitted from the plurality of light emitting devices ED.

For example, the first optical layer 117a may be disposed in each of the plurality of pixels PX or may be disposed in some pixels PX disposed in the same row, but embodiments of the present disclosure are not limited thereto. For example, the first optical layer 117a may be disposed in each of the plurality of pixels PX, or the plurality of pixels PX may share one first optical layer 117a. For another example, each of the plurality of sub-pixels may separately include a first optical layer 117a, but embodiments of the present disclosure are not limited thereto.

According to the present disclosure, the second optical layer 117b may be disposed on the passivation layer 116 in the display area AA. For example, the second optical layer 117b may surround the first optical layer 117a. For example, the second optical layer 117b may be in contact with a side surface of the first optical layer 117a. For example, the second optical layer 117b may be disposed in an area between the plurality of pixels PX. However, embodiments of the present disclosure are not limited thereto. For example, the second optical layer 117b may be a diffusion layer, a window diffusion layer, or the like, but embodiments of the present disclosure are not limited thereto.

The second optical layer 117b may be formed of an organic insulating material, but embodiments of the present disclosure are not limited thereto. The second optical layer 117b may be formed of the same material as the first optical layer 117a, but embodiments of the present disclosure are not limited thereto. For example, the first optical layer 117a may include fine particles, and the second optical layer 117b may not include fine particles. For example, the second optical layer 117b may be formed of siloxane, but embodiments of the present disclosure are not limited thereto.

For example, a thickness of the first optical layer 117a may be less than a thickness of the second optical layer 117b, but embodiments of the present disclosure are not limited thereto. Accordingly, in a plan view, an area in which the first optical layer 117a is disposed may include a concave portion recessed from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light emitting devices ED. For example, the second electrode CE2 may include a transparent conductive oxide such as indium tin oxide (ITO) or indium zinc oxide (IZO), but embodiments of the present disclosure are not limited thereto. For example, the second electrode CE2 may be in contact with the cathode 135. For example, the second electrode CE2 may overlap the entire first optical layer 117a, and may overlap a portion of the second optical layer 117b.

The second electrode CE2 may extend continuously in the first direction of the substrate 110. Accordingly, the second electrode CE2 may be connected in common to the plurality of pixels PX arranged in the first direction of the substrate 110. For example, the second electrode CE2 may be connected in common to the plurality of pixels PX.

According to the present disclosure, the second electrode CE2 may continuously extend on the first optical layer 117a, the second optical layer 117b, and the light emitting device ED. The area in which the first optical layer 117a is disposed may include the concave portion recessed from the upper surface of the second optical layer 117b. Accordingly, since a first portion of the second electrode CE2 disposed on the first optical layer 117a is disposed along the concave portion, the first portion may be disposed at a lower position than a second portion of the second electrode CE2 disposed on the second optical layer 117b.

The third optical layer 117c may be disposed on the second electrode CE2. The third optical layer 117c may overlap the plurality of light emitting devices ED and the first optical layer 117a. For example, the third optical layer 117c may not overlap the second optical layer 117b. Since the third optical layer 117c is disposed on the second electrode CE2 and the plurality of light emitting devices ED, spot (of mura) that may occur in some of the plurality of light emitting devices ED may be improved. For example, when the plurality of light emitting devices ED are transferred on the substrate 110 of the display panel 100, a region in which an gap between the plurality of light emitting devices ED is not uniform due to a process deviation, or the like may be formed. When the gap between the plurality of light emitting devices ED is not uniform, a light emitting area of each of the plurality of light emitting devices ED may be non-uniformly disposed, and thus a spot (or mura) may be recognized by a user. Accordingly, since the third optical layer 117c for uniformly diffusing light on an upper portion of the plurality of light emitting devices ED is formed, it is possible to reduce visibility of light emitted from some light emitting devices ED as spots (or mura). Therefore, since the light emitted from the plurality of light emitting devices ED is uniformly diffused by the third optical layer 117c and extracted to the outside of the display panel 100, the luminance uniformity of the display device may be improved.

The third optical layer 117c may be formed of an organic insulating material in which fine particles are distributed, but embodiments of the present disclosure are not limited thereto. For example, the third optical layer 117c may be formed of siloxane in which fine metal particles such as titanium dioxide (TiO₂) particles are distributed, but embodiments of the present disclosure are not limited thereto. For example, the third optical layer 117c may be formed of the same material as the first optical layer 117a, but embodiments of the present disclosure are not limited thereto. For example, the third optical layer 117c may be a diffusion layer, an upper diffusion layer, or the like, but embodiments of the present disclosure are not limited thereto.

According to the present disclosure, light from the plurality of light emitting devices ED may be scattered by fine particles distributed in the third optical layer 117c and emitted to the outside of the display panel 100. The third optical layer 117c may evenly mix the light emitted from the plurality of light emitting devices ED to further improve luminance uniformity of the display device. In addition, light extraction efficiency of the display device may be improved by the light scattered from the plurality of fine particles, and thus the display device may be driven at a low power.

In the display area AA, a black matrix BM may be disposed on the second electrode CE2, the first optical layer 117a, the second optical layer 117b, and the third optical layer 117c. For example, the black matrix BM may fill a contact hole of the second optical layer 117b. Since the black matrix BM may cover the display area AA, color mixture of light of the plurality of sub pixels and reflection of external light may be reduced. For example, since the black matrix BM is disposed within a contact hole in which the second electrode CE2 and the contact electrode CCE are connected, light leakage between the plurality of adjacent sub-pixels may be prevented.

For example, the black matrix BM may be formed of an opaque material, but embodiments of the present disclosure are not limited thereto. For example, the black matrix BM may be an organic insulating material to which a black pigment or a black dye is added, but embodiments of the present disclosure are not limited thereto.

Referring to FIG. 8, a cover layer 118 may be disposed on the black matrix BM in the display area AA. The cover layer 118 may protect an element under the cover layer 118, for example, the cover layer 118 may be formed of an organic insulating material, but embodiments of the present disclosure are not limited thereto. For example, the cover layer 118 may be formed of a photo resist, polyimide (PI), a photo acryl-based material, or the like, but embodiments of the present disclosure are not limited thereto. For example, the cover layer 118 may be an overcoating layer, an insulating layer, or the like, but embodiments of the present disclosure are not limited thereto.

A polarizing layer 280 may be disposed on the cover layer 118 via a first adhesive layer 291. A cover member 120 may be disposed on the polarizing layer 280 via a second adhesive layer 295. For example, the first adhesive layer 291 and the second adhesive layer 295 may include an optically clear adhesive (OCA), an optically clear resin (OCR), a pressure sensitive adhesive (PSA) or the like, but embodiments of the present disclosure are not limited thereto.

According to the present disclosure, the plurality of pad electrodes PE may be disposed on the third insulating layer 115c in the second non-display area NA2. For example, a portion of the plurality of pad electrodes PE may be exposed by the passivation layer 116. For example, the plurality of pad electrodes PE may be electrically connected to the 2-4th connection line 122d through a contact hole of the third insulating layer 115c.

An adhesive film ACF may be disposed on the plurality of pad electrodes PE. The adhesive film ACF may be an adhesive layer in which conductive balls are distributed in an insulating material, but embodiments of the present disclosure are not limited thereto. When heat or pressure is applied to the adhesive film ACF, the conductive ball may have conductive characteristics in a region to which heat or pressure is applied. An adhesive film ACF may be disposed between the plurality of pad electrodes PE and the flexible circuit board (or flexible film) 170, so that a flexible circuit board (or flexible film) 170 may be attached to or bonded to the plurality of pad electrodes PE. For example, the adhesive film ACF may be an anisotropic conductive film (ACF), but embodiments of the present disclosure are not limited thereto.

The flexible circuit board (or flexible film) 170 may be disposed on the adhesive film ACF. The flexible circuit board (or flexible film) 170 may be electrically connected to the plurality of pad electrodes PE through the adhesive film ACF. Therefore, signals output from the flexible circuit board (or flexible film) 170 and the printed circuit board 160 may be transmitted to the pixel driving circuit PD of the display area AA through the plurality of pad electrodes PE, the 2-4th connection line 122d, the 2-3th connection line 122c, the 2-1th connection line 122b, and the 2-1th connection line 122a.

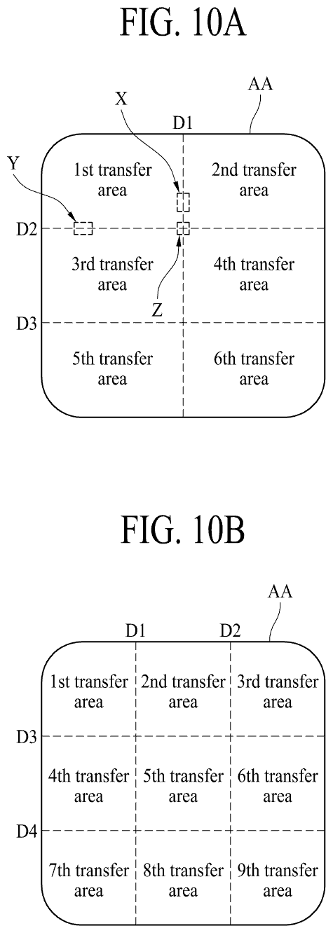

FIG. 10A is a plan view illustrating a transfer area of a display device according to an embodiment of the present disclosure. And, FIG. 10B is a plan view illustrating a transfer area of a display device according to another embodiment of the present disclosure.

Referring to FIGS. 10A and 10B, a plurality of light emitting devices may be transferred to a display area AA of a display device through a plurality of transfer processes.

For example, as shown in FIG. 10A, the plurality of light emitting devices may be transferred to the display area AA by performing a transfer process six times on first to sixth transfer regions using a transfer stamp capable of transferring the plurality of light emitting devices. In this case, the first to sixth transfer regions may be partitioned by a first boundary line D1 in a vertical direction and a second boundary line D2 and a third boundary line D3 in a horizontal direction, and the plurality of sub-pixels may be disposed in each of the first to sixth transfer regions.

Alternatively, as shown in FIG. 10b, the plurality of light emitting devices may be transferred to the display area AA by performing a transfer process nine times on first to ninth transfer regions using a transfer stamp capable of transferring the plurality of light emitting devices. In this case, the first to ninth transfer areas may be partitioned by a first boundary line D1 and a second boundary line D2 in the vertical direction, a third boundary line D3 and a fourth boundary line D4 in the horizontal direction, and the plurality of sub-pixels may be disposed in each of the first to sixth transfer regions.

In performing the transfer process according to FIGS. 10A and 10B, a transfer error or a transfer deviation may occur between each transfer process using a transfer stamp.

For example, there was no transfer error during the transfer process to the first transfer region, but the transfer error may occur during the transfer process to the second transfer region. Alternatively, although no transfer error occurred in both the transfer process to the first transfer region and the transfer process to the second transfer region, a deviation may occur between a light emitting characteristics of the plurality of light emitting devices transferred to the plurality of sub-pixels in the first transfer region and a light emitting characteristics of the plurality of light emitting devices transferred to the plurality of sub-pixels in the second transfer region.

In this way, if there is a difference in a presence or absence of the transfer error or a difference in characteristics of light emitting devices between the plurality of transfer regions, a difference in light emission intensity may occur between the plurality of transfer regions. In this case, a spot may occur near the boundary lines D1, D2, D3, and D4 between the plurality of transfer regions, thereby deteriorating display quality.

Hereinafter, a display device capable of reducing a problem of occurrence of spots near the boundary line between the plurality of transfer regions will be described.

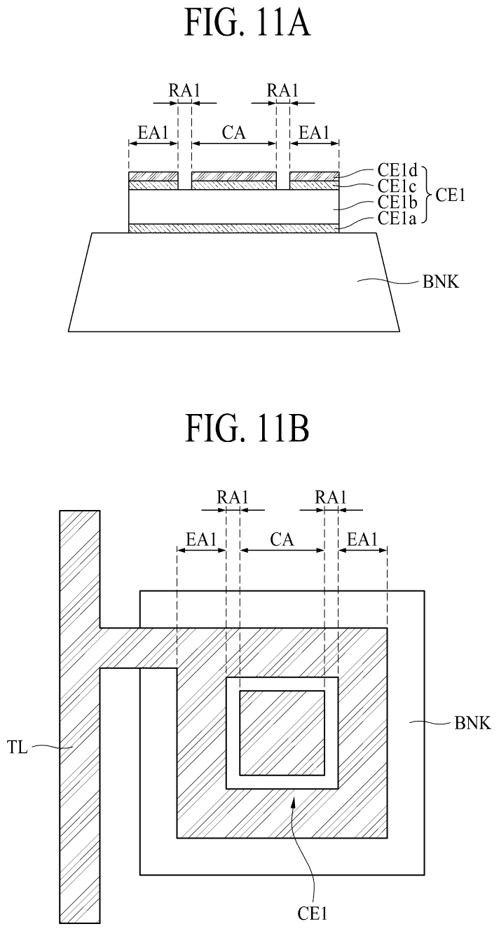

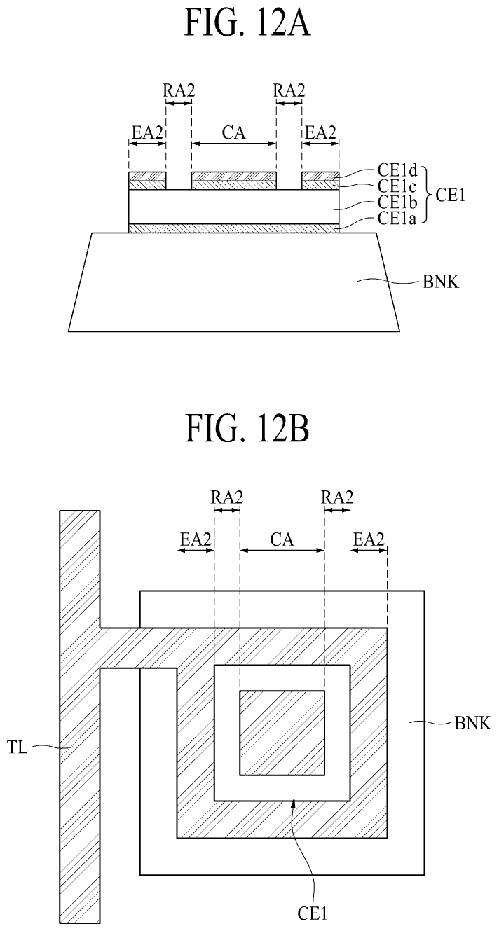

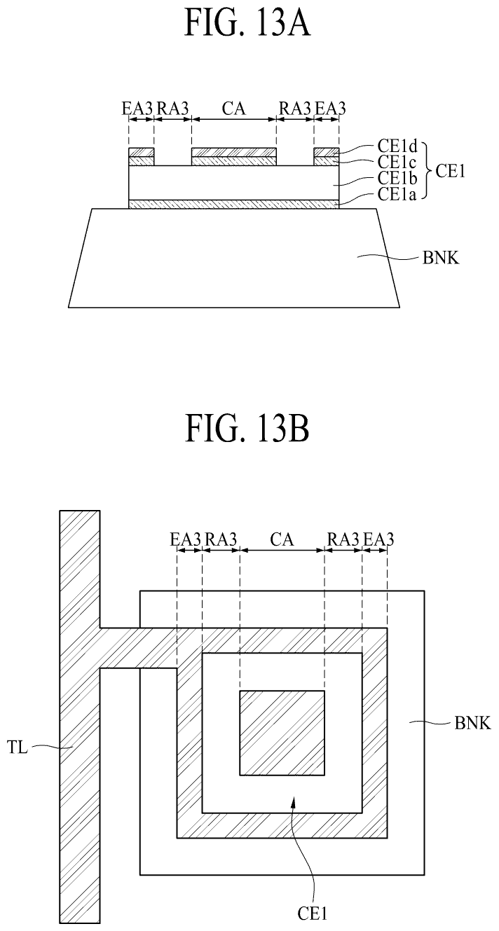

FIGS. 11A and 11B are a cross-sectional view and a plan view of a sub-pixel according to an embodiment of the present disclosure. And, FIGS. 12A and 12B are a cross-sectional view and a plan view of a sub-pixel according to another embodiment of the present disclosure. And, FIGS. 13A and 13B are a cross-sectional view and a plan view of a sub-pixel according to another embodiment of the present disclosure. And, FIGS. 14A and 14B are a cross-sectional view and a plan view of a sub-pixel according to another embodiment of the present disclosure.

FIGS. 11A, 12A, 13A, and 14A are respectively illustrating only the bank BNK and the first electrode CE1 in FIG. 9 described above. And, FIG. 11B is a view illustrating a state in which a signal line TL according to an example is connected to the first electrode CE1 according to FIG. 11A. And, FIG. 12B is a view illustrating a state in which a signal line TL according to an example is connected to the first electrode CE1 according to FIG. 12A. And, FIG. 13B is a view illustrating a state in which a signal line TL according to an example is connected to the first electrode CE1 according to FIG. 13A. And, FIG. 14B is a view illustrating a state in which a signal line TL according to an example is connected to the first electrode CE1 according to FIG. 14A.

As may be seen from each drawing, each sub-pixel includes a bank BNK and a first electrode CE1 disposed on the bank BNK. The first electrode CE1 may include a first conductive layer CE1a, a second conductive layer CE1b, a third conductive layer CE1c, and a fourth conductive layer CE1d.

In this case, the first electrode CE1 disposed in each sub-pixel may include a central area CA, reflection areas RA1, RA2, RA3, and RA4, and edge areas EA1, EA2, EA3, and EA4.

The central area CA is an area in which the above-described solder pattern SDP of FIG. 9 is disposed to be in contact with the solder pattern SDP of FIG. 9. The central area CA of the first electrode CE1 is electrically connected to the light emitting device ED by the solder pattern SDP of FIG. 9. In the central area CA, an upper surface of the first electrode CE1 may be formed of the fourth conductive layer CE1d. For example, the fourth conductive layer CE1d including a transparent conductive oxide layer having good adhesion to the solder pattern SDP of FIG. 9 and corrosion resistance and acid resistance may constitute the upper surface of the first electrode CE1 in the central area CA.

In this case, a width of the central area CA may be the same in all sub-pixels according to various embodiments of FIGS. 11A, 12A, 13A, and 14A.

As shown in FIGS. 11B, 12B, 13B, and 14B, the central area CA may have a rectangular structure, for example, a square structure, but is not limited thereto.

The reflection areas RA1, RA2, RA3, and RA4 are areas disposed between the central area CA and the edge areas EA1, EA2, EA3, and EA4. The reflection areas RA1, RA2, RA3, and RA4 may not be in contact with the solder pattern SDP of FIG. 9. In the reflection areas RA1, RA2, RA3, and RA4, the upper surface of the first electrode CE1 may be formed of the second conductive layer CE1b. Since the third and fourth conductive layers CE1c and CE1d constituting the first electrode CE1 are removed from the reflection areas RA1, RA2, RA3, and RA4, the second conductive layer CE1b positioned below the third and fourth conductive layers CE1c and CE1d may be exposed on upper surfaces of the reflection areas RA1, RA2, RA3, and RA4. For example, the second conductive layer CE1b, which has good reflection efficiency and may function as a reflector, may constitute a upper surface of the first electrode CE1 in the reflection areas RA1, RA2, RA3, and RA4.

In this case, widths of the reflection areas RA1, RA2, RA3, and RA4 may be configured to be different from each other in the sub-pixel according to various embodiments. For example, the width of the first reflection area RA1 of the sub-pixel according to an embodiment of FIGS. 11A and 11B is the relatively smallest, and the width of the second reflection area RA2 of the sub-pixel according to another embodiment of FIGS. 12A and 12B is greater than the width of the first reflection area RA1, and the width of the third reflection area RA3 of the sub-pixel according to another embodiment of FIGS. 13A and 13B may be greater than the width of the second reflection area RA2, and the width of the fourth reflection area RA4 of the sub-pixel according to another embodiment of FIGS. 14A and 14B may be greater than the width of the third reflection area RA3.

Therefore, the subpixels according to another embodiment of FIGS. 12a and 12b may have better reflection efficiency than the subpixels according to the embodiment of FIGS. 11a and 11b, the subpixels according to another embodiment of FIGS. 13a and 13b may have better reflection efficiency than the subpixels according to another embodiment of FIGS. 12a and 12b, and the subpixels according to another embodiment of FIGS. 14a and 14b may have better reflection efficiency than the subpixels according to the other embodiments of FIGS. 13a and 13b.

As shown in FIGS. 11B, 12B, 13B, and 14B, the reflection areas RA1, RA2, RA3, and RA4 may have a rectangular frame structure, for example, a square frame structure, while surrounding the central area CA, but are not limited thereto.

Referring to FIG. 9 described above, the reflection areas RA1, RA2, RA3, and RA4 may be covered by the passivation layer 116.

The edge areas EA1, EA2, EA3, and EA4 are areas disposed outside the reflection areas RA1, RA2, RA3, and RA4. The edge areas EA1, EA2, EA3, and EA4 may not be in contact with the solder pattern SDP of FIG. 9. In the edge areas EA1, EA2, EA3, and EA4, an upper surface of the first electrode CE1 may be formed of the fourth conductive layer CE1d. For example, the fourth conductive layer CE1d including a transparent conductive oxide layer having corrosion resistance and acid resistance may constitute the upper surface of the first electrode CE1 in the edge areas EA1, EA2, EA3, and EA4. In the edge areas EA1, EA2, EA3, and EA4, the upper surface of the first electrode CE1 may be formed of the same material layer as upper top surface of the first electrode CE1 in the central area CA, for example, the same fourth conductive layer CE1d.

In this case, widths of the edge areas EA1, EA2, EA3, and EA4 may be configured to be different from each other in sub-pixels of various embodiments. The widths of the edge areas EA1, EA2, EA3, and EA4 in the sub-pixels of various embodiments may be opposite to the widths of the reflection areas RA1, RA2, RA3, and RA4 in the sub-pixels of various embodiments. For example, the width of the first edge area EA1 of the sub-pixel according to the embodiment of FIGS. 11A and 11B is the relatively largest, and the width of the second edge area EA2 of the sub-pixel according to the other embodiment of FIGS. 12A and 12B is smaller than the width of the first edge area EA1, and the width of the third edge area EA3 of the sub-pixel according to another embodiment of FIGS. 13A and 13B is smaller than the width of the second edge area EA2, and the width of the fourth edge area EA4 of the sub-pixel according to another embodiment of FIGS. 14A and 14B may be smaller than the width of the third edge area EA3.

As shown in FIGS. 11B, 12B, 13B, and 14B, the edge areas EA1, EA2, EA3, and EA4 may include a rectangular frame structure surrounding the reflection areas RA1, RA2, RA3, and RA4, but are not limited thereto.

The edge areas EA1, EA2, EA3 and EA4 of the first electrode CE1 may extend while passing through an end of the bank BNK to be connected to the signal line TL. The signal line TL may be integrally formed with the edge areas EA1, EA2, EA3 and EA4 of the first electrode CE1. Accordingly, the signal line TL may include the first conductive layer CE1a, the second conductive layer CE1b, the third conductive layer CE1c, and the fourth conductive layer CE1d, but is not limited thereto.

Referring to FIG. 9 described above, the edge areas EA1, EA2, EA3 and EA4 may be covered by the passivation layer 116.

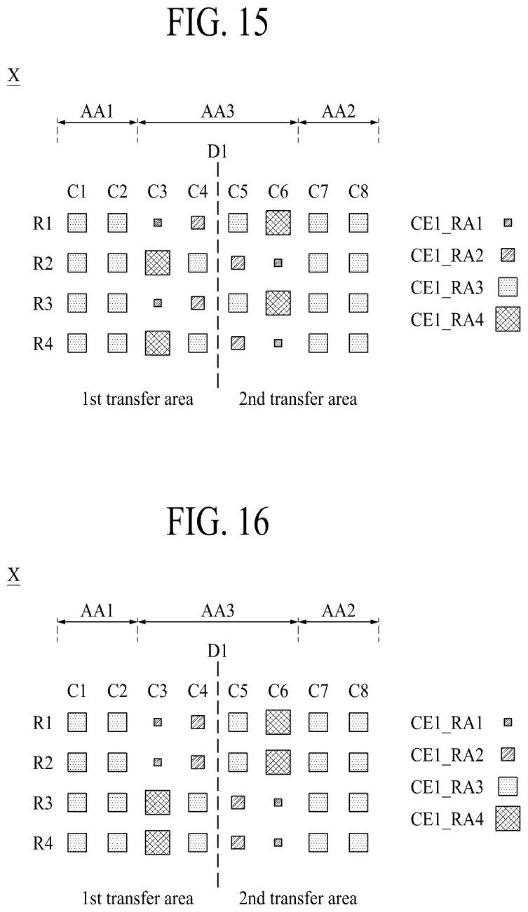

FIG. 15 illustrates a plurality of sub-pixels disposed in a X region of FIG. 10A according to an embodiment of the present disclosure, for example, in a region near a first boundary line D1 between a first transfer region and a second transfer region.

As can be seen from FIG. 15, for example, a first display area AA1 is disposed at a left side and a second display area AA2 is disposed at a right side based on the first boundary line D1 between the first transfer region and the second transfer region.

In addition, a third display area AA3 is disposed between the first display area AA1 and the second display area AA2. A partial area of the third display area AA3, for example, a left area, may be disposed at the left side of the first boundary line D1, and the remaining area of the third display area AA3, for example, a right area, may be disposed at the right side of the first boundary line D1.

Accordingly, the plurality of light emitting devices of the plurality of sub-pixels may be transferred to the first display area AA1 and a partial area of the third display area AA3 corresponding to the first transfer region through a first transfer process. In addition, the plurality of light emitting devices of the plurality of sub-pixels may be transferred to the second display area AA2 and the remaining areas of the third display area AA3 corresponding to the second transfer region through a second transfer process.

For convenience, sub-pixels having a 4×8 matrix structure in first to fourth rows R1 to R4 and first to eighth rows C1 to C8 are shown. In this case, the first display area AA1 has sub-pixels having a 4×2 matrix structure in the first to fourth rows R1 to R4 and the first to second rows C1 to C2, and the second display area AA2 has sub-pixels having a 4×2 matrix structure in the first to fourth rows R1 to R4 and the seventh to eighth rows C7 to C8, and the third display area AA3 has sub-pixels having a 4×4 matrix structure in the first to fourth rows R1 to R4 and the third to sixth rows C3 to C6. In this case, the matrix structure of the sub-pixels constituting the third display area AA3 may be variously changed. For example, the number of the plurality of columns C3 to C6 constituting the third display area AA3 may be variously changed.

A first electrode CE1 having a reflection area of the same width may be disposed in all of the plurality of sub-pixels in the first display area AA1. For example, the first electrode CE1 having a reflection area of an intermediate width among a plurality of widths applied to the entire display area may be disposed in the plurality of sub-pixels in the first display area AA1. For example, when the reflection area of the plurality of widths applied to the entire display area are composed of the first to fourth reflection areas RA1, RA2, RA3, and RA4 described above, the first electrode CE1_RA3 having the third reflection area may be disposed in the plurality of sub-pixels in the first display area AA1. In some cases, the first electrode CE1_RA2 having the second reflection area may be disposed in the plurality of sub-pixels in the first display area AA1. For example, as illustrated, the first electrode CE1_RA3 having the third reflection area may be disposed in all of the plurality of sub-pixels having the 4×2 matrix structure of the first to fourth rows R1 to R4 and the first to second columns C1 to C2 in the first display area AA1.

Similarly, a first electrode CE1 having a reflection area of the same width may be disposed in the plurality of sub-pixels within the second display area AA2. For example, like the first display area AA1, the first electrode CE1 having the reflection area of the intermediate width among the plurality of widths applied to the entire display area may be disposed in a plurality of sub-pixels in the second display area AA2. For example, when the reflection area having the plurality of widths applied to the entire display area are composed of the first to fourth reflection areas RA1, RA2, RA3, and RA4 described above, the first electrode CE1_RA3 having the third reflection area may be disposed in the plurality of sub-pixels in the second display area AA2 as shown. In some cases, the first electrode CE1_RA2 having the second reflection area may be disposed in the plurality of sub-pixels in the second display area AA2. For example, as shown, the first electrode CE1_RA3 having a third reflection area may be disposed in all of the plurality of sub-pixels having the 4×2 matrix structure of the first to fourth rows R1 to R4 and the seventh to eighth columns C7 to C8.

A first electrodes CE1 having reflection areas of different widths may be disposed in the plurality of sub-pixels in the third display area AA3. For example, among the plurality of widths applied to the entire display area, the first electrode CE1 having the reflection area of the width of all sizes may be disposed in the plurality of sub-pixels in the third display area AA3. Specifically, the first electrodes CE1 having reflection area with the smallest width to the first electrode CE1 having the reflection area with the largest width may be disposed in the plurality of sub-pixels in the third display area AA3. For example, when the reflection area having the plurality of widths applied to the entire display area are composed of the first to fourth reflection areas RA1, RA2, RA3, and RA4 described above, as shown, the first electrode CE1_RA1 having the first reflection area, the first electrode CE1_RA2 having the second reflection area, the first electrode CE1_RA3 having the third reflection area, and the first electrode CE1_RA4 having the fourth reflection area may be disposed in the plurality of sub-pixels in the third display area AA3. Although not shown, a first electrode having a fifth reflection area greater than the fourth reflection area RA4, a first electrode having a sixth reflection area greater than the fifth reflection area, and the like may be additionally included in the third display area AA3.

In odd rows R1 and R3, the first electrode may be disposed so that the width of the reflection area gradually increases in the plurality of subpixels from the third column C3 to the sixth column C6, and in even rows R2 and R4, the first electrode may be disposed so that the width of the reflection area gradually decreases in the plurality of subpixels from the third column C3 to the sixth column C6. For example, in odd rows R1 and R3, the first electrode CE1_RA1 having the first reflection area, the first electrode CE1_RA2 having the second reflection area, the first electrode CE1_RA3 having the third reflection area, and the first electrode CE1_RA4 having the fourth reflection area are sequentially disposed in the plurality of subpixels from the third column C3 to the sixth column C6. And, in an even row R2 and R4, the first electrode CE1_RA4 having the fourth reflection area, the first electrode CE1_RA3 having the third reflection area, the first electrode CE1_RA2 having the second reflection area, and the first electrode CE1_RA1 having the first reflection area may be sequentially disposed in the plurality of subpixels from the third column C3 to the sixth column C6.

In some cases, in the odd rows R1 and R3, the first electrode may be disposed so that the width of the reflection area gradually decreases in the plurality of sub-pixels from the third row C3 to the sixth row C6, and in the even rows R2 and R4, the first electrode may be disposed so that the width of the reflection area gradually increases in the plurality of sub-pixels from the third row C3 to the sixth row C6.

Meanwhile, a main light emitting device ED is disposed in the odd rows R1 and R3, and a redundancy light emitting device ED is disposed in the even rows R2 and R4, so that one sub-pixel may be constituted by a combination of the two rows. In this case, in the odd rows R1 and R3 in which the main light emitting device ED is disposed, the width of the reflection area gradually increases or decreases as the columns C3 to C6 increase, and in contrast, in the even rows R2 and R4 in which the redundancy light emitting device ED is disposed, the first electrode may be disposed so that the width of the reflection area gradually decreases or increases as the columns C3 to C6 increase.

As described above, according to an configuration of the present disclosure, in the third display area AA3 including the first boundary line D1 between the first transfer region and the second transfer region, the first electrode may be disposed so that the width of the reflection area gradually increases in odd rows or even rows, and the first electrode may be disposed so that the width of the reflection area gradually decreases in even rows or odd rows. Accordingly, reflectance of the first electrode is variously distributed in the plurality of sub-pixels in the third display area AA3, even if a difference in the presence or absence of the transfer error or a difference in characteristics of light emitting devices occurs between the first transfer region and the second transfer region, a problem of occurrence of spots near the first boundary line D1 between the first transfer region and the second transfer region may be solved or reduced.

FIG. 16 illustrates a plurality of sub-pixels disposed in a X region of FIG. 10A according to another embodiment of the present disclosure, for example, in a region near a first boundary line D1 between a first transfer region and a second transfer region.

According to FIG. 15 described above, in the third display area AA3 including the first boundary line D1 between the first transfer region and the second transfer region, the first electrode is disposed so that the width of the reflection area gradually increases as the columns C3 to C6 increase in odd rows, and the width of the reflection area gradually decreases as the columns C3 to C6 increase in even rows, or the first electrode is disposed so that the width of the reflection area gradually decreases as the columns C3 to C6 increase in odd rows, and the width of the reflection area gradually increases as the columns C3 to C6 increase in even rows.

On the other hand, according to FIG. 16, in the third display area AA3 including the first boundary line D1 between the first transfer region and the second transfer region, the first electrode may be disposed so that the width of the reflection area gradually increases as the columns C3 to C6 increase in two adjacent rows, for example, in the first row R1 and the second row R2, and the first electrode may be disposed so that the width of the reflection area gradually decreases as the columns C3 to C6 increase in two adjacent rows, for example, in the third row R3 and the fourth row R4. Alternatively, in the third display area AA3 including the first boundary line D1 between the first transfer region and the second transfer region, the first electrode may be disposed so that the width of the reflection area gradually decreases as the columns C3 to C6 increase in two adjacent rows, for example, in the first row R1 and the second row R2, and the first electrode may be disposed so that the width of the reflection area gradually increases as the columns C3 to C6 increase in the other two adjacent rows, for example, in the third row R3 and the fourth row R4.

The main light emitting device ED is disposed in odd rows R1 and R3, and the redundancy light emitting device ED is disposed in even rows R2 and R4, so that one sub-pixel may be constituted by a combination of the two rows.

In this case, the first electrode may be disposed such that the width of the reflection area gradually increases or decreases as the columns C3 to C6 increase in two adjacent rows R1 and R2 in which the main light emitting device ED and the redundancy light emitting device ED are disposed, and the first electrode may be disposed such that the width of the reflection area gradually decreases or increases as the columns C3 to C6 increase in the other two adjacent rows R3 and R4 in which the main light emitting device ED and the redundancy light emitting device ED are disposed.

As described above, according to another configuration of the present disclosure, in the third display area AA3 including the first boundary line D1 between the first transfer region and the second transfer region, the first electrode may be disposed so that the width of the reflection area gradually increases or decreases as the column increases in two adjacent rows, and a first electrode may be disposed so that the width of the reflection area gradually decreases or increases as the column increases in the other two adjacent rows. Accordingly, reflectance of the first electrode is variously distributed in the plurality of sub-pixels in the third display area AA3, even if the difference in the presence or absence of the transfer error or the difference in characteristics of light emitting devices occurs between the first transfer region and the second transfer region, the problem of occurrence of spots near the first boundary line D1 between the first transfer region and the second transfer region may be solved or reduced.

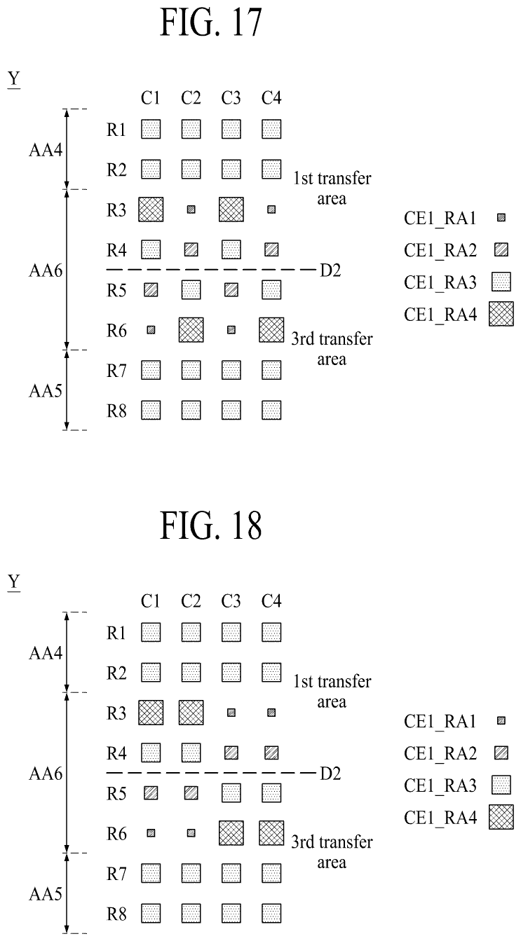

FIG. 17 illustrates a plurality of sub-pixels disposed in a Y region of FIG. 10A according to another embodiment of the present disclosure, for example, in a region near a second boundary line D2 between a first transfer region and a third transfer region.

As can be seen from FIG. 17, for example, a fourth display area AA4 is disposed on an upper side and a fifth display area AA5 is disposed on the lower side based on the second boundary line D2 between the first transfer region and the third transfer region.

In addition, a sixth display area AA6 is disposed between the fourth display area AA4 and the fifth display area AA5. A partial area of the sixth display area AA6, for example, an upper area, may be disposed above the second boundary line D2, and the remaining area of the sixth display area AA6, for example, a lower area, may be disposed below the second boundary line D2.

Accordingly, the plurality of light emitting devices of the plurality of sub-pixels may be transferred to the fourth display area AA4 and a partial area of the sixth display area AA6 corresponding to the first transfer region through a first transfer process. In addition, the plurality of light emitting devices of the plurality of sub-pixels may be transferred to the fifth display area AA5 and the remaining areas of the sixth display area AA6 corresponding to the third transfer region through a third transfer process.

For convenience, sub-pixels having an 8×4 matrix structure in first to eighth rows R1 to R8 and first to fourth columns C1 to C4 are shown. In this case, the fourth display area AA4 has sub-pixels having a 2×4 matrix structure in the first to second rows R1 to R2 and the first to fourth columns C1 to C4, and the fifth display area AA5 has sub-pixels having a 2×4 matrix structure in the seventh to eighth rows R7 to R8 and the first to fourth columns C1 to C4, and the sixth display area AA6 has sub-pixels having a 4×4 matrix structure in the third to sixth rows R3 to R6 and the first to fourth columns C1 to C4. In this case, the matrix structure of the sub-pixels constituting the sixth display area AA6 may be variously changed. For example, the number of the plurality of rows R3 to R6 constituting the sixth display area AA6 may be variously changed.

A first electrode CE1 having a reflection area of the same width may be disposed in all of the plurality of sub-pixels in the fourth display area AA4. For example, the first electrode CE1 having a reflection area of an intermediate width among a plurality of widths applied to the entire display area may be disposed in the plurality of sub-pixels in the fourth display area AA4. For example, when the reflection area of the plurality of widths applied to the entire display area are composed of the first to fourth reflection areas RA1, RA2, RA3, and RA4 described above, the first electrode CE1_RA3 having the third reflection area may be disposed in the plurality of sub-pixels in the fourth display area AA4. In some cases, the first electrode CE1_RA2 having the second reflection area may be disposed in the plurality of sub-pixels in the fourth display area AA4. For example, as illustrated, the first electrode CE1_RA3 having the third reflection area may be disposed in all of the plurality of sub-pixels having the 2×4 matrix structure of the first to second rows R1 to R2 and the first to fourth columns C1 to C4 in the fourth display area AA4.

Similarly, a first electrode CE1 having a reflection area of the same width may be disposed in the plurality of sub-pixels within the fifth display area AA5. For example, like the fourth display area AA4, the first electrode CE1 having the reflection area of the intermediate width among the plurality of widths applied to the entire display area may be disposed in a plurality of sub-pixels in the fifth display area AA5. For example, when the reflection area having the plurality of widths applied to the entire display area are composed of the first to fourth reflection areas RA1, RA2, RA3, and RA4 described above, the first electrode CE1_RA3 having the third reflection area may be disposed in the plurality of sub-pixels in the fifth display area AA5 as shown. In some cases, the first electrode CE1_RA2 having the second reflection area may be disposed in the plurality of sub-pixels in the fifth display area AA5. For example, as shown, the first electrode CE1_RA3 having a third reflection area may be disposed in all of the plurality of sub-pixels having the 2×4 matrix structure of the seventh to eighth rows R7 to R8 and the first to fourth columns C1 to C4.

A first electrodes CE1 having reflection areas of different widths may be disposed in the plurality of sub-pixels in the sixth display area AA6. For example, among the plurality of widths applied to the entire display area, the first electrode CE1 having the reflection area of the width of all sizes may be disposed in the plurality of sub-pixels in the sixth display area AA6. Specifically, the first electrodes CE1 having reflection area with the smallest width to the first electrode CE1 having the reflection area with the largest width may be disposed in the plurality of sub-pixels in the sixth display area AA6. For example, when the reflection area having the plurality of widths applied to the entire display area are composed of the first to fourth reflection areas RA1, RA2, RA3, and RA4 described above, as shown, the first electrode CE1_RA1 having the first reflection area, the first electrode CE1_RA2 having the second reflection area, the first electrode CE1_RA3 having the third reflection area, and the first electrode CE1_RA4 having the fourth reflection area may be disposed in the plurality of sub-pixels in the sixth display area AA6. Although not shown, a first electrode having a fifth reflection area greater than the fourth reflection area RA4, a first electrode having a sixth reflection area greater than the fifth reflection area, and the like may be additionally included in the sixth display area AA6.

In odd columns C1 and C3, the first electrode may be disposed so that the width of the reflection area gradually decreases in the plurality of subpixels from the third row R3 to the sixth row R6, and in the even columns C2 and C4, the first electrode may be disposed so that the width of the reflection area gradually increases in the plurality of subpixels from the third row R3 to the sixth row R6. For example, in the odd columns C1 and C3, the first electrode CE1_RA4 having the fourth reflection area, the first electrode CE1_RA3 having the third reflection area, the first electrode CE1_RA2 having the second reflection area, and the first electrode CE1_RA1 having the first reflection area are sequentially disposed in a plurality of subpixels from the third row R3 to the sixth row R6. And, in an even column C2 and C4, the first electrode CE1_RA1 having the first reflection area, the first electrode CE1_RA2 having the second reflection area, the first electrode CE1_RA3 having the third reflection area, and the first electrode CE1_RA4 having the fourth reflection area may be sequentially disposed in the plurality of subpixels from the third row R3 to the sixth row R6.

In some cases, in the odd columns C1 and C3, a first electrode may be disposed so that the width of the reflection area gradually increases in the plurality of sub-pixels from the third row R3 to the sixth row R6, and in the even columns C2 and C4, the first electrode may be disposed so that the width of the reflection area gradually decreases in the plurality of sub-pixels from the third row R3 to the sixth row R6.

As described above, according to an configuration of the present specification, in the sixth display area AA6 including the second boundary line D2 between the first transfer region and the third transfer region, in the odd or even column, the first electrode may be disposed so that the width of the reflection area gradually increases as the rows R3 to R6 increase, and in the even or odd columns, the width of the reflection area may be disposed so that the width of the reflection area gradually decreases as the rows R3 to R6 increase. Accordingly, reflectance of the first electrode is variously distributed in a plurality of sub-pixels in the sixth display area AA6, even if a difference in the presence or absence of a transfer error or a difference in characteristics of light emitting devices occurs between the first transfer region and the third transfer region, a problem of occurrence of spots near the second boundary line D2 between the first transfer region and the third transfer region may be solved or reduced.

FIG. 18 illustrates a plurality of sub-pixels disposed in a Y region of FIG. 10A according to another embodiment of the present disclosure, for example, in a region near a second boundary line between a first transfer region and a third transfer region.

According to FIG. 17 described above, in the sixth display area AA6 including the second boundary line D2 between the first transfer region and the third transfer region, the first electrode is disposed so that the width of the reflection area gradually increases as the rows increases in odd columns, or the first electrode is disposed so that the width of the reflection area gradually decreases as the rows increases in even columns, or the first electrode is disposed so that the width of the reflection area gradually decreases as the rows increase in odd columns, and the width of the reflection area gradually increases as the rows increase in even columns.

On the other hand, according to FIG. 18, in the sixth display area AA6 including the second boundary line D2 between the first transfer region and the third transfer region, the first electrode may be disposed so that the width of the reflection area gradually decreases as the rows R3 to R6 increase in two adjacent columns, for example, in the first column C1 and the second column C2, and the first electrode may be disposed so that the width of the reflection area gradually increases as the rows R3 to R6 increase in two adjacent columns, for example, in the third column C3 and the fourth column C4. Alternatively, in the sixth display area AA6 including the second boundary line D2 between the first transfer region and the third transfer region, the first electrode may be disposed so that the width of the reflection area gradually increases as the rows R3 to R6 increase in two adjacent columns, for example, in the first column C1 and the second column C2, and the first electrode may be disposed so that the width of the reflection area gradually decreases as the rows R3 to R6 increase in the other two adjacent columns, for example, in the third column C3 and the fourth column C4.

As described above, according to another configuration of the present disclosure, in the sixth display area AA6 including the second boundary line D2 between the first transfer region and the third transfer region, the first electrode may be disposed so that the width of the reflection area gradually increases or decreases as the row increases in two adjacent columns, and the first electrode may be disposed so that the width of the reflection area gradually decreases or increases as the row increases in the other two adjacent columns. Accordingly, reflectance of the first electrode is variously distributed in a plurality of sub-pixels in the sixth display area AA6, even if the difference in the presence or absence of a transfer error or the difference in characteristics of light emitting devices occurs between the first transfer region and the third transfer region, a problem of occurrence of spots near the second boundary line D2 between the first transfer region and the third transfer region may be solved or reduced.

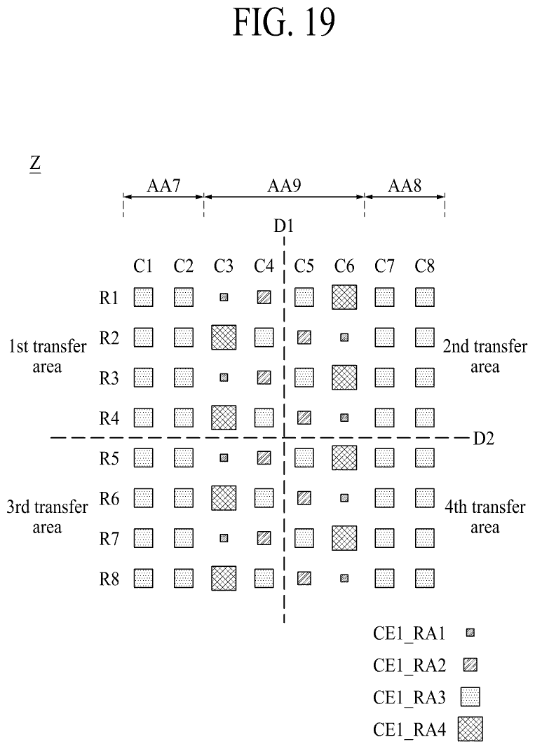

FIG. 19 illustrates a plurality of sub-pixels disposed in a Z region of FIG. 10A according to another embodiment of the present disclosure, for example, in a nearby region where a first boundary line D1 between a first transfer region and a second transfer region and a second boundary line D2 between a first transfer region and a third transfer region intersect.

As can be seen from FIG. 19, for example, a seventh display area AA7 is disposed at a left side and an eighth display area AA8 is disposed at a right side based on the first boundary line D1 between the first and second transfer regions and between the third and fourth transfer regions. In this case, a partial area of the seventh display area AA7, for example, an upper area, may be disposed in the first transfer region, and the remaining area of the seventh display area AA7, for example, a lower area, may be disposed in the third transfer region. A partial area of the eighth display area AA8, for example, an upper area, may be disposed in the second transfer region, and the remaining area of the eighth display area AA8, for example, a lower area, may be disposed in the fourth transfer region.

In addition, a ninth display area AA9 is disposed between the seventh display area AA7 and the eighth display area AA8. A partial area of the ninth display area AA9, for example, a left area, may be disposed at the left side of the first boundary line D1, and the remaining area of the ninth display area AA9, for example, a right area, may be disposed at the right side of the first boundary line D1. In this case, an upper left area of the ninth display area AA9 is disposed in the first transfer region, an upper right area of the ninth display area AA9 is disposed in the second transfer area, an lower left area of the ninth display area AA9 may be disposed in the third transfer region, and the lower right area of the ninth display area AA9 may be disposed in the fourth transfer region.

Accordingly, the plurality of light emitting devices of the plurality of sub-pixels are transferred to the upper area of the seventh display area AA7 and the upper left area of the ninth display area AA9 corresponding to the first transfer region through the first transfer process. In addition, the plurality of light emitting devices of the plurality of sub-pixels are transferred to the upper area of the eighth display area AA8 and the upper right area of the ninth display area AA9 corresponding to the second transfer region through the second transfer process. In addition, the plurality of light emitting devices of the plurality of sub-pixels are transferred to the lower area of the seventh display area AA7 and the lower left area of the ninth display area AA9 corresponding to the third transfer region through the third transfer process. In addition, the plurality of light emitting devices of the plurality of sub-pixels are transferred to the lower area of the eighth display area AA8 and the lower right area of the ninth display area AA9 corresponding to the fourth transfer region through the fourth transfer process.

For convenience, sub-pixels having an 8×8 matrix structure in the first to eighth rows R1 to R8 and the first to eighth columns C1 to C8 are shown. In this case, the seventh display area AA7 may have sub-pixels having an 8×2 matrix structure in the first to eighth rows R1 to R8 and the first to second columns C1 to C2, and the eighth display area AA8 may have sub-pixels having an 8×2 matrix structure in the first to eighth rows R1 to R8 and the seventh to eighth columns C7 to C8, and the ninth display area AA9 may have sub-pixels having an 8×4 matrix structure in the first to eighth rows R1 to R8 and the third to sixth columns C3 to C6. In this case, a matrix structure of a sub-pixel constituting the ninth display area AA9 may be variously changed. For example, the number of a plurality of columns C3 to C6 constituting the ninth display area AA9 may be variously changed.

A first electrode CE1 having a reflection area of the same width may be disposed in all of the plurality of sub-pixels in the seventh display area AA7. For example, the first electrode CE1 having a reflection area of an intermediate width among a plurality of widths applied to the entire display area may be disposed in the plurality of sub-pixels in the seventh display area AA7. For example, when the reflection area of the plurality of widths applied to the entire display area are composed of the first to fourth reflection areas RA1, RA2, RA3, and RA4 described above, the first electrode CE1_RA3 having the third reflection area may be disposed in the plurality of sub-pixels in the seventh display area AA7. In some cases, the first electrode CE1_RA2 having the second reflection area may be disposed in the plurality of sub-pixels in the seventh display area AA7. For example, as illustrated, the first electrode CE1_RA3 having the third reflection area may be disposed in all of the plurality of sub-pixels having the 8×2 matrix structure of the first to eighth rows R1 to R8 and the first to second columns C1 to C2 in the seventh display area AA7.

Similarly, a first electrode CE1 having a reflection area of the same width may be disposed in the plurality of sub-pixels within the eighth display area AA8. For example, like the seventh display area AA7, the first electrode CE1 having the reflection area of the intermediate width among the plurality of widths applied to the entire display area may be disposed in a plurality of sub-pixels in the eighth display area AA8. For example, when the reflection area having the plurality of widths applied to the entire display area are composed of the first to fourth reflection areas RA1, RA2, RA3, and RA4 described above, the first electrode CE1_RA3 having the third reflection area may be disposed in the plurality of sub-pixels in the eighth display area AA8 as shown. In some cases, the first electrode CE1_RA2 having the second reflection area may be disposed in the plurality of sub-pixels in the eighth display area AA8. For example, as shown, the first electrode CE1_RA3 having a third reflection area may be disposed in all of the plurality of sub-pixels having the 8×2 matrix structure of the first to eighth rows R1 to R8 and the seventh to eighth columns C7 to C8.

A first electrodes CE1 having reflection areas of different widths may be disposed in the plurality of sub-pixels in the ninth display area AA9. For example, among the plurality of widths applied to the entire display area, the first electrode CE1 having the reflection area of the width of all sizes may be disposed in the plurality of sub-pixels in the ninth display area AA9. Specifically, the first electrodes CE1 having reflection area with the smallest width to the first electrode CE1 having the reflection area with the largest width may be disposed in the plurality of sub-pixels in the ninth display area AA9. For example, when the reflection area having the plurality of widths applied to the entire display area are composed of the first to fourth reflection areas RA1, RA2, RA3, and RA4 described above, as shown, the first electrode CE1_RA1 having the first reflection area, the first electrode CE1_RA2 having the second reflection area, the first electrode CE1_RA3 having the third reflection area, and the first electrode CE1_RA4 having the fourth reflection area may be disposed in the plurality of sub-pixels in the ninth display area AA9. Although not shown, a first electrode having a fifth reflection area greater than the fourth reflection area RA4, a first electrode having a sixth reflection area greater than the fifth reflection area, and the like may be additionally included in the ninth display area AA9.

In odd rows R1, R3, R5, and R7, the first electrode may be disposed so that the width of the reflection area gradually increases in a plurality of subpixels from the third column C3 to the sixth column C6, and in even rows R2, R4, R6, and R8, the first electrode may be disposed so that the width of the reflection area gradually decreases in a plurality of subpixels from the third column C3 to the sixth column C6. For example, in odd rows R1, R3, R5, and R7, the first electrode CE1_RA1 having the first reflection area, the first electrode CE1_RA2 having the second reflection area, the first electrode CE1_RA3 having the third reflection area, and the first electrode CE1_RA4 having the fourth reflection area are sequentially disposed in a plurality of subpixels from the third column C3 to the sixth column C6. And, in an even row R2, R4, R6, and R8, the first electrode CE1_RA4 having the fourth reflection area in a plurality of subpixels, the first electrode CE1_RA3 having the third reflection area, the first electrode CE1_RA2 having the second reflection area, and the first electrode CE1_RA1 having the first reflection area may be sequentially disposed in a plurality of subpixels from the third column C3 to the sixth column C6, In some cases, in odd rows R1, R3, R5, and R7, a first electrode may be disposed so that the width of the reflection area gradually decreases in the plurality of sub-pixels from the third column C3 to the sixth column C6, and in even rows R2, R4, R6, and R8, the first electrode may be disposed so that the width of the reflection area gradually increases in the plurality of sub-pixels from the third column C3 to the sixth column C6.

Meanwhile, the main light emitting device ED is disposed in odd rows R1, R3, R5, and R7, and the redundancy light emitting device ED is disposed in even rows R2, R4, R6, and R8, so that one sub-pixel may be constituted by a combination of the two rows. In this case, in odd rows R1, R3, R5, and R7 in which the main light emitting device ED is disposed, a first electrode may be disposed so that the width of the reflection region gradually increases or decreases as the columns C3 to C6 increase, and in contrast, in even rows R2, R4, R6, and R8 in which the redundancy light emitting device ED is disposed, the width of the reflection region gradually decreases or increases as the columns C3 to C6 increase.

As described above, according to another configuration of the present disclosure, in the ninth display area AA9 including an area in which the first boundary line D1 and the second boundary line D2 intersect, a first electrode may be disposed so that the width of the reflection area gradually increases as the column increases in odd rows or even rows, and a first electrode may be disposed so that the width of the reflection area gradually decreases as the column increases in even rows or odd rows. Accordingly, the reflectance of the first electrode is variously distributed in a plurality of sub-pixels in the ninth display area AA9, even if a difference in the presence or absence of a transfer error or a difference in characteristics of light emitting elements occurs between the first to fourth transfer areas, a problem of occurrence of spots near the first boundary line D1 and the second boundary line D2 may be solved or reduced.

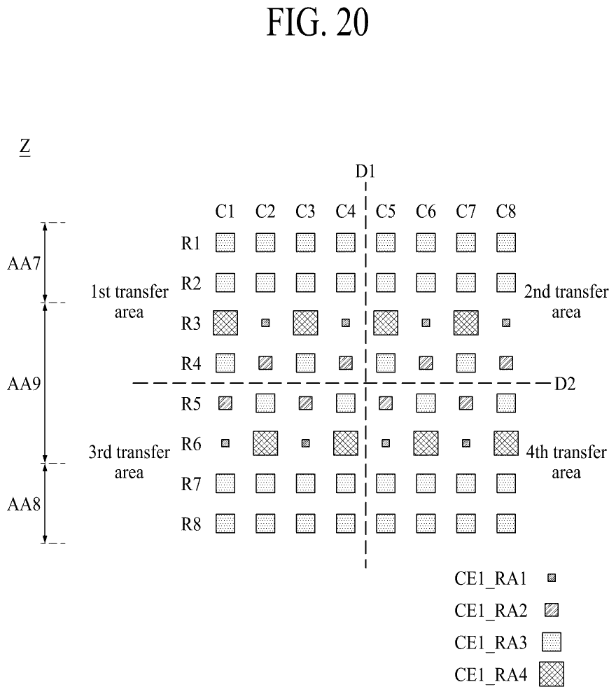

FIG. 20 illustrates a plurality of sub-pixels disposed in a Z region of FIG. 10A according to another embodiment of the present disclosure, for example, in a nearby region where a first boundary line between a first transfer region and a second transfer region and a second boundary line between a first transfer region and a third transfer region intersect.

As can be seen from FIG. 20, for example, a seventh display area AA7 is disposed at an upper side and an eighth display area AA8 is disposed at a lower side based on the second boundary line D2 between the first transfer region and the third transfer region and between the second transfer region and the fourth transfer region. In this case, a partial area of the seventh display area AA7, for example, a left area, may be disposed in the first transfer region, and the remaining area of the seventh display area AA7, for example, a right area, may be disposed in the second transfer region. A partial area of the eighth display area AA8, for example, a left area, may be disposed in the third transfer region, and the remaining area of the eighth display area AA8, for example, a right area, may be disposed in the fourth transfer region.

In addition, a ninth display area AA9 is disposed between the seventh display area AA7 and the eighth display area AA8. A partial area of the ninth display area AA9, for example, an upper area, may be disposed above the second boundary line D2, and the remaining area of the ninth display area AA9, for example, a lower area, may be disposed below the second boundary line D2. In this case, an upper left area of the ninth display area AA9 is disposed in the first transfer region, an upper right area of the ninth display area AA9 is disposed in the second transfer region, a lower left area of the ninth display area AA9 may be disposed in the third transfer region, and a lower right area of the ninth display area AA9 may be disposed in the fourth transfer region.

Accordingly, the plurality of light emitting devices of the plurality of sub-pixels are transferred to the left area of the seventh display area AA7 and the upper left area of the ninth display area AA9 corresponding to the first transfer region through the first transfer process. In addition, the plurality of light emitting devices of the plurality of sub-pixels are transferred to the right area of the seventh display area AA7 and the upper right area of the ninth display area AA9 corresponding to the second transfer region through the second transfer process. In addition, the plurality of light emitting devices of the plurality of sub-pixels are transferred to the left area of the eighth display area AA8 and the lower left area of the ninth display area AA9 corresponding to the third transfer region through the third transfer process. In addition, the plurality of light emitting devices of the plurality of sub-pixels are transferred to the right area of the eighth display area AA8 and the lower right area of the ninth display area AA9 corresponding to the fourth transfer region through the fourth transfer process.

For convenience, sub-pixels having an 8×8 matrix structure in the first to eighth rows R1 to R8 and the first to eighth columns C1 to C8 are shown. In this case, the seventh display area AA7 has sub-pixels having a 2×8 matrix structure in the first to second rows R1 to R2 and the first to eighth columns C1 to C8, and the eighth display area AA8 has sub-pixels having a 2×8 matrix structure in the seventh to eighth rows R7 to R8 and the first to eighth columns C1 to C8, and the ninth display area AA9 has sub-pixels having a 4×8 matrix structure in the third to sixth rows R3 to R6 and the first to eighth columns C1 to C8. In this case, the matrix structure of the sub-pixels constituting the ninth display area AA9 may be variously changed. For example, the number of the plurality of rows R3 to R6 constituting the ninth display area AA9 may be variously changed.

A first electrode CE1 having a reflection area of the same width may be disposed in all of the plurality of sub-pixels in the seventh display area AA7. For example, the first electrode CE1 having a reflection area of an intermediate width among a plurality of widths applied to the entire display area may be disposed in the plurality of sub-pixels in the seventh display area AA7. For example, the first electrode CE1_RA3 having the third reflection area or the first electrode CE1_RA2 having the second reflection area may be disposed in the plurality of sub-pixels in the seventh display area AA7. For example, as illustrated, the first electrode CE1_RA3 having the third reflection area may be disposed in all of the plurality of sub-pixels having the 2×8 matrix structure of the first to second rows R1 to R2 and the first to eighth columns C1 to C8 in the seventh display area AA7.

Similarly, a first electrode CE1 having a reflection area of the same width may be disposed in the plurality of sub-pixels within the eighth display area AA8. For example, like the seventh display area AA7, the first electrode CE1 having the reflection area of the intermediate width among the plurality of widths applied to the entire display area may be disposed in a plurality of sub-pixels in the eighth display area AA8. For example, the first electrode CE1_RA3 having the third reflection area or the first electrode CE1_RA2 having the second reflection area may be disposed in the plurality of sub-pixels in the eighth display area AA8. For example, as shown, the first electrode CE1_RA3 having a third reflection area may be disposed in all of the plurality of sub-pixels having the 2×8 matrix structure in the seventh to eighth rows R7 to R8 and the first to eighth columns C1 to C8 in the eighth display area AA8.

A first electrodes CE1 having reflection areas of different widths may be disposed in the plurality of sub-pixels in the ninth display area AA9. For example, among the plurality of widths applied to the entire display area, the first electrode CE1 having the reflection area of the width of all sizes may be disposed in the plurality of sub-pixels in the ninth display area AA9. Specifically, the first electrodes CE1 having reflection area with the smallest width to the first electrode CE1 having the reflection area with the largest width may be disposed in the plurality of sub-pixels in the ninth display area AA9. For example, the first electrode CE1_RA1 having the first reflection area, the first electrode CE1_RA2 having the second reflection area, the first electrode CE1_RA3 having the third reflection area, and the first electrode CE1_RA4 having the fourth reflection area may be disposed in the plurality of sub-pixels in the ninth display area AA9.

In the odd columns C1, C3, C5, and C7, the first electrode may be disposed so that the width of the reflection area gradually decreases in a plurality of subpixels from the third row R3 to the sixth row R6, and in the even columns C2, C4, C6, and C8, a first electrode may be disposed so that the width of the reflection area gradually increases in a plurality of subpixels from the third row R3 to the sixth row R6. For example, in the odd columns C1, C3, C5, and C7, the first electrode CE1_RA4 having the fourth reflection area, the first electrode CE1_RA3 having the third reflection area, the first electrode CE1_RA2 having the second reflection area, and the first electrode CE1_RA1 having the first reflection area are sequentially disposed in a plurality of subpixels from the third row R3 to the sixth row R6. And, in an even column C2, C4, C6, and C8, the first electrode CE1_RA1 having the first reflection area, the first electrode CE1_RA2 having the second reflection area, the first electrode CE1_RA3 having the third reflection area, and the first electrode CE1_RA4 having the fourth reflection area may be sequentially disposed in a plurality of subpixels from the third row R3 to the sixth row R6.

In some cases, in the odd columns C1, C3, C5, and C7, the first electrode may be disposed so that the width of the reflection area gradually increases in the plurality of sub-pixels from the third row R3 to the sixth row R6, and in the even columns C2, C4, C6, and C8, the first electrode may be disposed so that the width of the reflection area gradually decreases in the plurality of sub-pixels from the third row R3 to the sixth row R6.

As described above, according to another configuration of the present disclosure, in the ninth display area AA9 including an area in which the first boundary line D1 and the second boundary line D2 intersect, the first electrode may be disposed so that the width of the reflection area gradually increases as the rows increase in the odd or even columns, and a first electrode may be disposed so that the width of the reflection area gradually decreases as the rows increase in the even or odd columns. Accordingly, the reflectance of the first electrode is variously distributed in a plurality of sub-pixels in the ninth display area AA9, even if a difference in the presence or absence of a transfer error or a difference in characteristics of light emitting devices occurs between the first to fourth transfer areas, a problem of occurrence of spots near the first boundary line D1 and the second boundary line D2 may be solved or reduced.

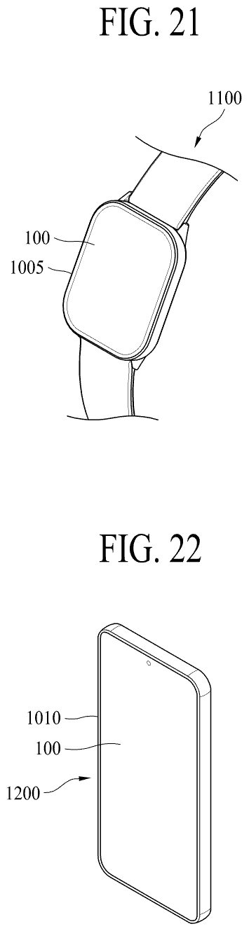

FIGS. 21 to 24 are diagrams illustrating devices to which a display device according to embodiments of the present disclosure is applied.

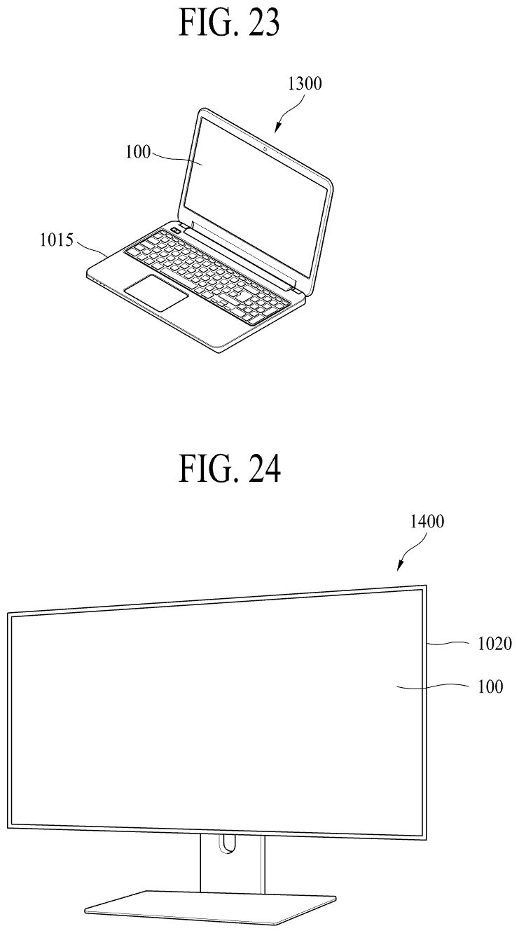

Referring to FIGS. 21 to 24, the display device according to embodiments of the present disclosure may be included in various devices or electronic devices. For example, various electronic devices may include a wearable device 1100 as shown in FIG. 21, a mobile device 1200 as shown in FIG. 22, a laptop 1300 as shown in FIG. 23, and a monitor or TV 1400 as shown in FIG. 24, but embodiments of the present disclosure are not limited thereto.

Each of the wearable device 1100, the mobile device 1200, the laptop 1300, and the monitor or TV 1400 may include a case unit 1005, 1010, 1015, and 1020 and a display panel 100 and a display device 1000 according to the above-described embodiments of the present disclosure.

For example, the display device according to an embodiment of the present disclosure includes a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), PDA (personal digital assistant), an MP3 player, a mobile medical device, a desktop PC, a laptop PC, a netbook computer, a workstation, a navigation, a vehicle display, a theater display, a television, a wall paper device, a signage device, a game device, a laptop, a game device, a monitor, a camera, a camcorder or a home appliance.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device, comprising:
a substrate;
a display area and a non-display area;
a pixel driving circuit in the display area on the substrate;
an insulating layer on the pixel driving circuit;
a bank disposed in a plurality of sub-pixels including a first sub-pixel and a second sub-pixel on the insulating layer;
a first electrode disposed on the bank and including a central area, an edge area, and a reflection area between the central area and the edge area; and
a light emitting device disposed on the first electrode and electrically connected to the first electrode and overlapping the bank,
wherein a width of the reflection area of the first electrode in the first sub-pixel is different from a width of the reflection area of the first electrode in the second sub-pixel.

2. The display device of claim 1, wherein a width of the central area of the first electrode in the first sub-pixel is same as a width of the central area of the first electrode in the second sub-pixel,
wherein the width of the reflection area of the first electrode in the first sub-pixel is greater than the width of the reflection area of the first electrode in the second sub-pixel, and
wherein a width of the edge area of the first electrode in the first sub-pixel is smaller than a width of the edge area of the first electrode in the second sub-pixel.

3. The display device of claim 1, wherein the first electrode includes a plurality of conductive layers including a first conductive layer and a second conductive layer different from the first conductive layer,
wherein an upper surface of the central area and the edge area of the first electrode includes the same first conductive layer, and
wherein an upper surface of the reflection area of the first electrode includes the second conductive layer.

4. The display device of claim 3, wherein the first conductive layer is made of a transparent conductive oxide, and the second conductive layer is disposed below the first conductive layer and made of a reflective material.

5. The display device of claim 1, wherein the first electrode and the light emitting device are electrically connected to each other by a solder pattern,
wherein the central area of the first electrode overlaps the solder pattern, and
wherein the reflection area and the edge area of the first electrode do not overlap the solder pattern.

6. The display device of claim 1, wherein the reflection area of the first electrode surrounds the central area of the first electrode, and the edge area of the first electrode surrounds the reflection area of the first electrode.

7. The display device of claim 1, further comprising a signal line disposed on the insulating layer and electrically connecting the first electrode with the pixel driving circuit, and
wherein the edge area of the first electrode extends to the signal line and is connected to the signal line.

8. The display device of claim 1, further comprising a passivation layer on the first electrode, and
wherein the passivation layer covers the reflection area and the edge area of the first electrode.

9. The display device of claim 1, further comprising:
a second electrode provided on the light emitting device and electrically connected to the light emitting device;
a first optical layer provided under the second electrode and covering a side surface of the light emitting device and a side surface of the bank; and
a second optical layer in contact with a side surface of the first optical layer.

10. The display device of claim 9, further comprising:
a black matrix on the second electrode; and
a third optical layer between the second electrode and the black matrix.

11. A display device, comprising:
a display area including a first display area, a second display area, and a third display area between the first display area and the second display area;
a plurality of light emitting devices disposed in a plurality of sub-pixels having a matrix structure in the display area; and
a plurality of first electrodes electrically connected to the plurality of light emitting devices in the plurality of sub-pixels, each first electrode including a central area, an edge area, and a reflection area between the central area and the edge area,
wherein widths of the reflection areas of the plurality of first electrodes are different from each other in the plurality of sub-pixels in the third display area.

12. The display device of claim 11, wherein widths of the reflection areas of the plurality of first electrodes in the plurality of sub-pixels in the first display area and the second display area are same to each other.

13. The display device of claim 11, wherein the plurality of first electrodes in the plurality of sub-pixels in the third display area include the plurality of first electrodes having the reflection areas of the widths of all sizes from the reflection area with a smallest width to the reflection area with a largest width among a plurality of widths applied to the entire display area.

14. The display device of claim 11, wherein a width of the reflection area of the plurality of first electrodes in the plurality of sub-pixels in the third display area gradually increases or decreases as row or column of the matrix structure increases.

15. The display device of claim 14, wherein the width of the reflection area of the plurality of first electrodes in the plurality of sub-pixels in the third display area gradually increases or decreases as the column increases in an odd row and gradually decreases or increases as the column increases in an even row.

16. The display device of claim 14, wherein the width of the reflection area of the plurality of first electrodes in the plurality of sub-pixels in the third display area gradually increases or decreases as the column increases in two adjacent rows and gradually decreases or increases as the column increases in another two adjacent rows.

17. The display device of claim 14, wherein the width of the reflection area of the plurality of first electrodes in the plurality of sub-pixels in the third display area gradually increases or decreases as the rows increase in an odd column and gradually decreases or increases as the rows increase in an even column.

18. The display device of claim 14, wherein the width of the reflection area of the plurality of first electrodes in the plurality of sub-pixels in the third display area gradually increases or decreases as the rows increase in two adjacent columns, and gradually decreases or increases as the rows increase in another two adjacent columns.

19. A display device, comprising:
a display area including a first display area, a second display area at a right side of the first display area, a third display area between the first display area and the second display area, a fourth display area at a left side of the first display area, a fifth display area below the fourth display area, and a sixth display area between the fourth display area and the fifth display area;
a plurality of light emitting devices in a plurality of sub-pixels having a matrix structure in the display area; and
a plurality of first electrodes electrically connected to the plurality of light emitting devices in the plurality of sub-pixels and including a central area, an edge area, and a reflection area between the central area and the edge area,
wherein a width of the reflection area of the plurality of first electrodes in the plurality of sub-pixels in the third display area gradually increases or decreases as a column of the matrix structure increases, and
wherein a width of the reflection area of the plurality of first electrodes in the plurality of sub-pixels in the sixth display area gradually increases or decreases as a row of the matrix structure increases.

20. The display device of claim 19, wherein widths of reflection areas of the plurality of first electrodes in the plurality of sub-pixels in the first display area, the second display area, the fourth display area, and the fifth display area are same.
